(19) United States
(12) Patent Application Publication
(10) Pub. No.: US 2026/0173669 A1
(43) Pub. Date: Jun. 18, 2026

(54) DISPLAY DEVICE, METHOD OF MANUFACTURING THE DISPLAY DEVICE, AND ELECTRONIC DEVICE INCLUDING THE DISPLAY DEVICE

(71) Applicant: SAMSUNG DISPLAY CO., LTD., YONGIN-SI (KR)

(72) Inventors: Jingyu KIM, Yongin-si (KR); JUNGYUN JO, Yongin-si (KR)

(21) Appl. No.: 19/266,359

(22) Filed: Jul. 11, 2025

(30) Foreign Application Priority Data
Dec. 17, 2024 (KR) 10-2024-0188668

(51) Int. Cl. H10K 59/124; H10K 59/12

(52) U.S. Cl. CPC H10K 59/124; H10K 59/1201

(57) ABSTRACT

A display device includes a first electrode disposed in a first pixel area on a substrate, a first protecting pattern covering at least a portion of the first electrode, a first insulating pattern covering at least a portion of each of the first electrode and first protecting pattern, a second electrode disposed on the first insulating pattern and at least partially overlapping the first electrode, a third electrode disposed in a second pixel area spaced apart from the first pixel area, a second protecting pattern covering at least a portion of the third electrode, a second insulating pattern covering at least a portion of each of the third electrode and the second protecting pattern, and a fourth electrode disposed on the second insulating pattern and at least partially overlapping the third electrode. The second electrode is connected to the first electrode. The fourth electrode is connected to the third electrode.

### CROSS-REFERENCE TO RELATED APPLICATIONS

This application claims priority under 35 U.S.C. § 119 to Korean Patent Application No. 10-2024-0188668, filed on December 17, 2024, the disclosure of which is incorporated by reference herein in its entirety.

### TECHNICAL FIELD

Embodiments of the present disclosure relate to a display device, a method of manufacturing the display device, and an electronic device including the display device.

### DISCUSSION OF RELATED ART

A display device is a device that provides visual information to a user by displaying images. Among various types of display devices, organic light emitting diode (OLED) display devices have recently gained significant attention due to their high contrast, fast response time, and potential for thin, flexible form factors.

A typical display device includes a plurality of light-emitting elements, each of which emits light to form part of an image. In such devices, each light-emitting element generally includes a pixel electrode, which may be formed with a multilayer structure to achieve desired electrical and optical properties.

### SUMMARY

Embodiments of the present disclosure provide a display device including a pixel electrode that is protected against oxidation.

Embodiments of the present disclosure provide a method of manufacturing the display device.

Embodiments of the present disclosure provide an electronic device including the display device.

A display device according to embodiments of the present disclosure includes a first electrode disposed in a first pixel area on a substrate, a first protecting pattern covering at least a portion of the first electrode, a first insulating pattern covering at least a portion of each of the first electrode and the first protecting pattern, a second electrode disposed on the first insulating pattern and at least partially overlapping the first electrode, a third electrode disposed in a second pixel area spaced apart from the first pixel area on the substrate, a second protecting pattern covering at least a portion of the third electrode, a second insulating pattern covering at least a portion of each of the third electrode and the second protecting pattern, and a fourth electrode disposed on the second insulating pattern and at least partially overlapping the third electrode. The second electrode is connected to the first electrode, and the fourth electrode is connected to the third electrode.

In embodiments of the present disclosure, the second electrode may be connected to the first electrode.

In embodiments of the present disclosure, the fourth electrode may be connected to the third electrode.

In embodiments of the present disclosure, the first protecting pattern may cover a side surface of the first electrode, and the second protecting pattern covers a side surface of the third electrode.

In embodiments of the present disclosure, the first protecting pattern may further cover an upper surface of the first electrode, and the second protecting pattern further covers an upper surface of the third electrode.

In embodiments of the present disclosure, the display device may further include a third insulating pattern covering the second insulating pattern.

In embodiments of the present disclosure, the fourth electrode may be disposed on the third insulating pattern.

In embodiments of the present disclosure, the first electrode and the second electrode may be connected to each other through a first contact hole formed in the first insulating pattern.

In embodiments of the present disclosure, the third electrode and the fourth electrode may be connected to each other through a second contact hole formed in the second insulating pattern and the third insulating pattern.

In embodiments of the present disclosure, a distance between the third electrode and the fourth electrode in an area not overlapping the second contact hole may be greater than a distance between the first electrode and the second electrode in an area not overlapping the first contact hole.

In embodiments of the present disclosure, each of the first protecting pattern and the second protecting pattern may include amorphous carbon.

In embodiments of the present disclosure, the first protecting pattern may be an oxidation preventing film that prevents oxidation of at least a portion of the first electrode, and the second protecting pattern may be an oxidation that prevents film preventing oxidation of at least a portion of the third electrode.

In embodiments of the present disclosure, a side surface of the first electrode and the first insulating pattern may be discontinuous from each other.

A method of manufacturing a display device according to embodiments of the present disclosure includes forming a first electrode in a first pixel area on a substrate, forming a first protecting pattern covering at least a portion of the first electrode, forming a first insulating pattern covering at least a portion of the first protecting pattern, forming a first contact hole in the first insulating pattern, forming a second electrode on the first insulating pattern, forming a third electrode in a second pixel area spaced apart from the first pixel area on the substrate, forming a second protecting pattern covering at least a portion of the third electrode, forming a second insulating pattern covering at least a portion of the second protecting pattern, forming a third insulating pattern covering the second insulating pattern, forming a second contact hole in the second insulating pattern and the third insulating pattern, and forming a fourth electrode on the second insulating pattern.

In embodiments of the present disclosure, the second electrode may fill the first contact hole.

In embodiments of the present disclosure, the fourth electrode may fill the second contact hole.

In embodiments of the present disclosure, forming the first protecting pattern and the second protecting pattern may include forming a protecting layer covering the first electrode and the third electrode, and removing portions of the protecting layer in the first pixel area and the second pixel area.

In embodiments of the present disclosure, forming the first insulating pattern may include forming a preliminary insulating layer covering the first protecting pattern and the second protecting pattern, forming an etch stopper in the first pixel area on the preliminary insulating layer, and removing at least a portion of the preliminary insulating layer.

In embodiments of the present disclosure, by the forming of the first protecting pattern covering at least a portion of the first electrode, oxidation of a portion of the first electrode may be prevented.

An electronic device according to embodiments of the present disclosure includes a display device including a power source configured to supply power to a display panel. The display panel includes a first electrode disposed in a first pixel area on a substrate, a first protecting pattern covering at least a portion of the first electrode, a first insulating pattern covering at least a portion of each of the first electrode and the first protecting pattern, a second electrode disposed on the first insulating pattern and at least partially overlapping the first electrode, a third electrode disposed in a second pixel area spaced apart from the first pixel area on the substrate, a second protecting pattern covering at least a portion of the third electrode, a second insulating pattern covering at least a portion of each of the third electrode and the second protecting pattern, and a fourth electrode disposed on the second insulating pattern and at least partially overlapping the third electrode . The second electrode is connected to the first electrode, and the fourth electrode is connected to the third electrode.

In embodiments of the present disclosure, the first protecting pattern may cover a side surface of the first electrode, and the second protecting pattern covers a side surface of the third electrode.

In embodiments of the present disclosure, the first protecting pattern further may cover an upper surface of the first electrode, and the second protecting pattern further covers an upper surface of the third electrode.

In embodiments of the present disclosure, the display device may further include a third insulating pattern covering the second insulating pattern.

In embodiments of the present disclosure, the fourth electrode may be disposed on the third insulating pattern.

In embodiments of the present disclosure, each of the first protecting pattern and the second protecting pattern may include amorphous carbon.

In embodiments of the present disclosure, the first protecting pattern may be an oxidation preventing film that prevents oxidation of at least a portion of the first electrode, and the second protecting pattern may be an oxidation preventing film that prevents oxidation of at least a portion of the third electrode.

In embodiments of the present disclosure, the electronic device may further include a processor, a memory having stored application programs for execution by the processor, and a user interface configured to sense user input via touch or cursor select of an icon presented on the display panel. Upon receipt of the user input, the processor is caused to execute one or more of the stored application programs to perform functions of one or more of a smartphone, camera, smart TV, monitor, smartwatch, tablet, automotive display, or AR/VR headset.

A display device according to embodiments of the present disclosure includes a first electrode disposed in a first pixel area on a substrate, a first protecting pattern covering at least a portion of the first electrode, a first insulating pattern covering at least a portion of each of the first electrode and the first protecting pattern, a second electrode disposed on the first insulating pattern and at least partially overlapping the first electrode, a third electrode disposed in a second pixel area spaced apart from the first pixel area in the plan view on the substrate, a second protecting pattern covering at least a portion of the third electrode, a second insulating pattern covering at least a portion of each of the third electrode and the second protecting pattern, and a fourth electrode disposed on the second insulating pattern and at least partially overlapping the third electrode.

Accordingly, oxidation of a portion of each of the first electrode and the third electrode may be prevented or reduced.

### BRIEF DESCRIPTION OF THE DRAWINGS

The above and other features of the present disclosure will become more apparent by describing in detail embodiments thereof with reference to the accompanying drawings.

FIG. 1 is a perspective view illustrating a display device according to embodiments of the present disclosure.

FIG. 2 is a cross-sectional view of the display device of FIG. 1 taken along line I-I`.

FIG. 3 is an enlarged cross-sectional view of an area X of FIG. 2.

FIGS. 4 to 20 are cross-sectional views illustrating a method of manufacturing the display device of FIG. 2 according to embodiments of the present disclosure.

FIG. 21 is a block diagram illustrating an electronic device according to embodiments of the present disclosure.

FIG. 22 is a schematic diagram of an electronic device according to various embodiments of the present disclosure.

FIG. 23 is a diagram illustrating an electronic device according to an embodiment of the present invention.

### DETAILED DESCRIPTION OF THE EMBODIMENTS

Embodiments of the present disclosure will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

Spatially relative terms, such as “beneath”, “below”, “lower”, “under”, “above”, “upper”, etc., may be used herein for ease of description to describe one element or feature’s relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

It will be understood that when a component is referred to as being “on”, “connected to”, “coupled to”, or “adjacent to” another component, it can be directly on, connected, coupled, or adjacent to the other component, or intervening components may be present. When components are referred to as being “connected” to each other, it is to be understood that the components may be physically and/or electrically connected to each other. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art, for example, within ± 30%, 20%, 10% or 5% of the stated value. Further, it is to be understood that while parameters may be described herein as having “about” a certain value, according to embodiments, the parameter may be exactly the certain value or approximately the certain value within a measurement error as would be understood by a person having ordinary skill in the art. Other uses of these terms and similar terms to describe the relationships between components should be interpreted in a like fashion.

In high-performance display devices such as organic light-emitting diode (OLED) panels, it is often necessary to stack multiple functional layers such as, for example, electrodes, insulating films, and protective structures, within each pixel area. However, when certain inorganic insulating materials are directly formed in contact with electrode layers, for example, those containing silver (Ag), oxygen diffusion can occur, leading to unwanted oxidation of the electrode material. This oxidation may degrade electrical conductivity, impair image quality, or reduce the long-term reliability of the display device.

Embodiments of the present disclosure address this issue by introducing a multilayer electrode structure in which a protecting pattern such as, for example, a film composed of amorphous carbon, is interposed between a side surface of the lower electrode and the overlying inorganic insulating film. This protecting pattern physically separates the reactive electrode material from oxygen-radical-containing dielectric layers, which may prevent oxidation. The protecting pattern may be formed using a carbon-based protective layer that is selectively etched to expose only specific contact areas of the electrode.

Through this structure, the display device may effectively inhibit oxidation of electrode portions while maintaining compatibility with conventional thin-film deposition and patterning techniques. As a result, embodiments may improve both the electrical performance and manufacturability of the display panel, including, for example, in compact, high-resolution OLED applications.

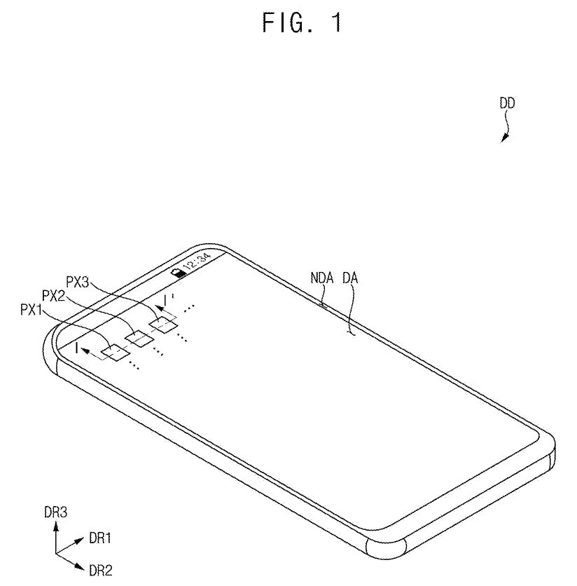

FIG. 1 is a perspective view illustrating a display device according to embodiments of the present disclosure.

Referring to FIG. 1, a display device DD may include a display area DA and a non-display area NDA. The display area DA is an area in which an image is displayed. For example, the display area DA may be an area in which light is generated and in which an image is displayed by adjusting transmittance of light provided from an external light source. The non-display area NDA may surround at least a portion of the display area DA. In embodiments of the present disclosure, the non-display area NDA is an area in which an image is not displayed. However, this disclosure is not necessarily limited thereto, and an image may be displayed in a portion of the non-display area NDA according to embodiments. The non-display area NDA may include a plurality of drivers.

A plurality of pixel areas may be disposed in the display area DA. For example, a first pixel area PX1, a second pixel area PX2, and a third pixel area PX3 may be disposed in the display area DA. Each of the first pixel area PX1, the second pixel area PX2, and the third pixel area PX3 may emit light. In embodiments of the present disclosure, the first pixel area PX1, the second pixel area PX2, and the third pixel area PX3 may emit light having different wavelengths. For example, the first pixel area PX1 may emit red light, the second pixel area PX2 may emit green light, and the third pixel area PX3 may emit blue light. However, this disclosure is not necessarily limited thereto. The first pixel area PX1, the second pixel area PX2, and the third pixel area PX3 may be spaced apart from each other in a plan view. For example, the second pixel area PX2 may be spaced apart from the first pixel area PX1 in a first direction DR1, and the third pixel area PX3 may be spaced apart from the second pixel area PX2 in the first direction DR1. However, this disclosure is not necessarily limited thereto. The plurality of pixel areas may be generally disposed throughout the display area DA. For example, the plurality of pixel areas may be generally disposed throughout the display area DA along the first direction DR1 and a second direction DR2 crossing the first direction DR1. As each of the plurality of pixel areas emits light in the display area DA, the display area DA may display an image.

In embodiments of the present disclosure, the first direction DR1 and the second direction DR2 crossing the first direction DR1 may be defined. For example, the second direction DR2 may be substantially perpendicular to the first direction DR1. However, this disclosure is not necessarily limited thereto, and the second direction DR2 may form an acute angle or an obtuse angle with the first direction DR1. In addition, a third direction DR3 crossing a plane formed by the first direction DR1 and the second direction DR2 may be defined. For example, the third direction DR3 may be substantially perpendicular to the plane formed by the first direction DR1 and the second directions DR2. However, this disclosure is not necessarily limited thereto, and the third direction DR3 may form an acute angle or an obtuse angle with the plane formed by the first direction DR1 and the second direction DR2.

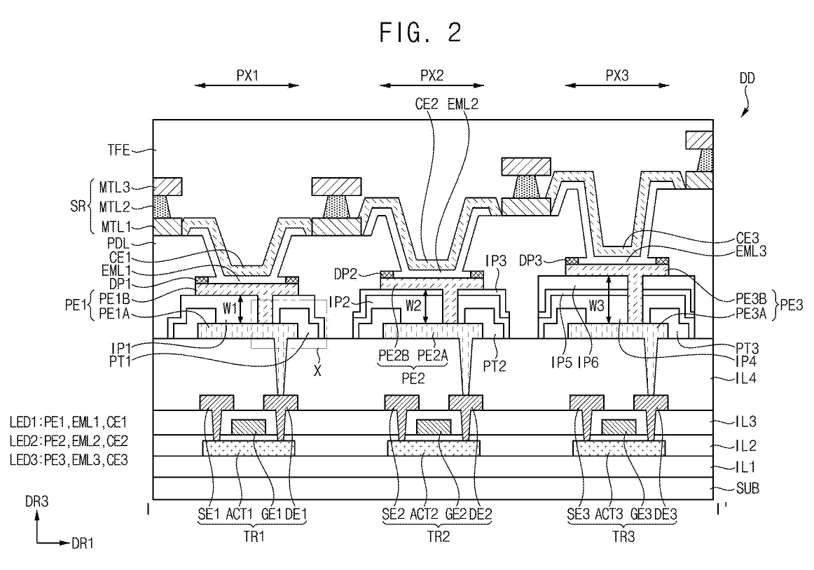

FIG. 2 is a cross-sectional view of the display device of FIG. 1 taken along line I-I`.

Referring to FIG. 2, a display device DD may include a substrate SUB, a first transistor TR1, a second transistor TR2, a third transistor TR3, a first insulating layer IL1, a second insulating layer IL2, a third insulating layer IL3, a fourth insulating layer IL4, a first light-emitting element LED1, a second light-emitting element LED2, a third light-emitting element LED3, a first protecting pattern PT1, a second protecting pattern PT2, a third protecting pattern PT3, a first insulating pattern IP1, a second insulating pattern IP2, a third insulating pattern IP3, a fourth insulating pattern IP4, a fifth insulating pattern IP5, a sixth insulating pattern IP6, a first dummy pattern DP1, a second dummy pattern DP2, a third dummy pattern DP3, a pixel defining layer PDL, a separator SR, and an encapsulation layer TFE.

The first transistor TR1 may include a first contact electrode SE1, a first gate electrode GE1, a first active pattern ACT1, and a second contact electrode DE1. The second transistor TR2 may include a third contact electrode SE2, a second gate electrode GE2, a second active pattern ACT2, and a fourth contact electrode DE2. The third transistor TR3 may include a fifth contact electrode SE3, a third gate electrode GE3, a third active pattern ACT3, and a sixth contact electrode DE3.

The first light-emitting element LED1 may include a first pixel electrode PE1, a first intermediate layer EML1, and a first common electrode CE1. The second light-emitting element LED2 may include a second pixel electrode PE2, a second intermediate layer EML2, and a second common electrode CE2. The third light-emitting element LED3 may include a third pixel electrode PE3, a third intermediate layer EML3, and a third common electrode CE3.

The substrate SUB may be a base of the display device DD. In embodiments of the present disclosure, the substrate SUB may be formed of a transparent resin substrate. Example of the transparent resin substrate may include a polyimide substrate. In this case, the polyimide substrate may include a first organic layer, a first barrier layer, a second organic layer, and/or the like. In embodiments, the substrate SUB may include, for example, a quartz substrate (e.g., a synthetic quartz substrate, a fluorine-doped quartz substrate), a calcium fluoride substrate, a sodalime glass substrate, a non-alkali glass substrate, and/or the like. These materials may be used alone or in combination with each other.

The first insulating layer IL1 may be disposed on the substrate SUB. The first insulating layer IL1 may prevent metal atoms or impurities from being diffused from the substrate SUB to the first transistor TR1, the second transistor TR2, and the third transistor TR3. In addition, when a surface of the substrate SUB is not uniform, the first insulating layer IL1 may improve flatness of the surface of the substrate SUB. The first insulating layer IL1 may include inorganic materials such as, for example, silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The first active pattern ACT1, the second active pattern ACT2, and the third active pattern ACT3 may be disposed on the first insulating layer IL1. Each of the first active pattern ACT1, the second active pattern ACT2, and the third active pattern ACT3 may include a first contact area, a second contact area, and a channel area disposed between the first contact area and the second contact area. Each of the first active pattern ACT1, the second active pattern ACT2, and the third active pattern ACT3 may include an inorganic semiconductor (e.g., amorphous silicon, polysilicon, a metal oxide semiconductor,), an organic semiconductor, and/or the like. These materials may be used alone or in combination with each other. The metal oxide semiconductor may include, for example, a binary compound (“ABₓ”), a ternary compound (“ABₓC_{y}”), a quaternary compound (“ABₓC_{y}D_{z}”), and/or the like including indium (“In”), zinc (“Zn”), gallium (“Ga”), tin (“Sn”), titanium (“Ti”), aluminum (“Al”), hafnium (“Hf”), zirconium (“Zr”), magnesium (“Mg”), and/or the like. These materials may be used alone or in combination with each other. For example, the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), and indium gallium zinc oxide (“IGZO”). These materials may be used alone or in combination with each other.

The second insulating layer IL2 may be disposed on the first insulating layer IL1. The second insulating layer IL2 may cover the first active pattern ACT1, the second active pattern ACT2, and the third active pattern ACT3. The second insulating layer IL2 may include inorganic materials such as, for example, silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The first gate electrode GE1, the second gate electrode GE2, and the third gate electrode GE3 may be disposed on the second insulating layer IL2. The first gate electrode GE1 may at least partially overlap the first active pattern ACT1 in the plan view. For example, the first gate electrode GE1 may overlap the channel area of the first active pattern ACT1 in the plan view. The second gate electrode GE2 may at least partially overlap the second active pattern ACT2 in the plan view. For example, the second gate electrode GE2 may overlap the channel area of the second active pattern ACT2 in the plan view. The third gate electrode GE3 may at least partially overlap the third active pattern ACT3 in the plan view. For example, the third gate electrode GE3 may overlap the channel area of the third active pattern ACT3 in the plan view. Each of the first gate electrode GE1, the second gate electrode GE2, and the third gate electrode GE3 may include, for example, a metal, an alloy, a metal nitride, a conductive metal oxide, a transparent conductive material, and/or the like. Examples of the metal include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide include indium tin oxide, indium zinc oxide, and/or the like. These materials may be used alone or in combination with each other. In addition, examples of the metal nitride include aluminum nitride (“AlNₓ”), tungsten nitride (“WNₓ”), chromium nitride (“CrNₓ”), and/or the like. These materials may be used alone or in combination with each other.

The third insulating layer IL3 may be disposed on the second insulating layer IL2. The third insulating layer IL3 may cover the first gate electrode GE1, the second gate electrode GE2, and the third gate electrode GE3. The third insulating layer IL3 may include inorganic materials such as, for example, silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The first contact electrode SE1, the second contact electrode DE1, the third contact electrode SE2, the fourth contact electrode DE2, the fifth contact electrode SE3, and the sixth contact electrode DE3 may be disposed on the third insulating layer IL3. The contact electrode SE1 may be connected to a portion of the first active pattern ACT1 through a first hole penetrating (or, defining through) the second insulating layer IL2 and the third insulating layer IL3. For example, the contact electrode SE1 may be connected to the first contact area of the first active pattern ACT1 through the first hole. The contact electrode DE1 may be connected to a portion of the first active pattern ACT1 through a second hole penetrating (or, defining through) the second insulating layer IL2 and the third insulating layer IL3. For example, the contact electrode DE1 may be connected to the second contact area of the first active pattern ACT1 through the second hole. The third contact electrode SE2 may be connected to a portion of the second active pattern ACT2 through a third hole penetrating (or, defining through) the second insulating layer IL2 and the third insulating layer IL3. For example, the third contact electrode SE2 may be connected to the first contact area of the second active pattern ACT2 through the third hole. The fourth contact electrode DE2 may be connected to a portion of the second active pattern ACT2 through a fourth hole penetrating (or, defining through) the second insulating layer IL2 and the third insulating layer IL3. For example, the fourth contact electrode DE2 may be connected to the second contact area of the second active pattern ACT2 through the fourth hole. The fifth contact electrode SE3 may be connected to a portion of the third active pattern ACT3 through a fifth hole penetrating (or, defining through) the second insulating layer IL2 and the third insulating layer IL3. For example, the contact electrode SE3 may be connected to the first contact area of the third active pattern ACT3 through the fifth hole. The sixth contact electrode DE3 may be connected to a portion of the third active pattern ACT3 through a sixth hole penetrating (or, defining through) the second insulating layer IL2 and the third insulating layer IL3. For example, the sixth contact electrode DE3 may be connected to the second contact area of the third active pattern ACT3 through the sixth hole. Each of the first contact electrode SE1, the second contact electrode DE1, the third contact electrode SE2, the fourth contact electrode DE2, the fifth contact electrode SE3, and the sixth contact electrode DE3 may include, for example, a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

The fourth insulating layer IL4 may be disposed on the third insulating layer IL3. The fourth insulating layer IL4 may cover the first contact electrode SE1, the second contact electrode DE1, the third contact electrode SE2, the fourth contact electrode DE2, the fifth contact electrode SE3 and the sixth contact electrode DE3. In embodiments of the present disclosure, the fourth insulating layer IL4 may include an organic material. For example, the fourth insulating layer IL4 may include phenolic resin, acrylic resin, polyimide resin, polyamide resin, siloxane resin, epoxy resin, and/or the like. These materials may be used alone or in combination with each other. This disclosure is not necessarily limited thereto, and in embodiments of the present disclosure, the fourth insulating layer IL4 may further include an inorganic material.

The first pixel electrode PE1 may include a first electrode PE1A and a second electrode PE1B. The second pixel electrode PE2 may include a third electrode PE2A and a fourth electrode PE2B. The third pixel electrode PE3 may include a fifth electrode PE3A and a sixth electrode PE3B.

The first electrode PE1A, the third electrode PE2A, and the fifth electrode PE3A may be disposed on the fourth insulating layer IL4. The first electrode PE1A may be disposed in the first pixel area PX1. The third electrode PE2A may be disposed in the second pixel area PX2. The fifth electrode PE3A may be disposed in the third pixel area PX3. For example, the first electrode PE1A, the third electrode PE2A, and the fifth electrode PE3A may be spaced apart from each other in the plan view. The first electrode PE1A may be connected to the first transistor TR1 through a seventh hole penetrating (or, defining through) the fourth insulating layer IL4. For example, the first electrode PE1A may be connected to the second contact electrode DE1 through the seventh hole. The third electrode PE2A may be connected to the second transistor TR2 through an eighth hole penetrating (or, defining through) the fourth insulating layer IL4. For example, the third electrode PE2A may be connected to the fourth contact electrode DE2 through the eighth hole. The fifth electrode PE3A may be connected to the third transistor TR3 through a ninth hole penetrating (or, defining through) the fourth insulating layer IL4. For example, the fifth electrode PE3A may be connected to the sixth contact electrode DE3 through the ninth hole.

The first protecting pattern PT1, the second protecting pattern PT2, and the third protecting pattern PT3 may be disposed on the fourth insulating layer IL4. The first protecting pattern PT1 may cover at least a portion of the first electrode PE1A. In embodiments of the present disclosure, the first protecting pattern PT1 may cover a side surface of the first electrode PE1A. In embodiments of the present disclosure, the first protecting pattern PT1 may further cover an upper surface of the first electrode PE1A. The upper surface of the first electrode PE1A may be a surface facing the second electrode PE1B. For example, the first protecting pattern PT1 may include a first opening exposing a portion of the upper surface of the first electrode PE1A. The second protecting pattern PT2 may cover at least a portion of the third electrode PE2A. In embodiments of the present disclosure, the second protecting pattern PT2 may cover a side surface of the third electrode PE2A. In embodiments of the present disclosure, the second protecting pattern PT2 may further cover an upper surface of the third electrode PE2A. The upper surface of the third electrode PE2A may be a surface facing the fourth electrode PE2B. For example, the second protecting pattern PT2 may include a second opening exposing a portion of the upper surface of the third electrode PE2A. The third protecting pattern PT3 may cover at least a portion of the fifth electrode PE3A. In embodiments of the present disclosure, the third protecting pattern PT3 may cover a side surface of the fifth electrode PE3A. In embodiments of the present disclosure, the third protecting pattern PT3 may further cover an upper surface of the fifth electrode PE3A. The upper surface of the fifth electrode PE3A may be a surface facing the sixth electrode PE3B. For example, the third protecting pattern PT3 may include a third opening exposing a portion of the upper surface of the fifth electrode PE3A. The first protecting pattern PT1, the second protecting pattern PT2, and the third protecting pattern PT3 may be spaced apart from each other in the plan view. For example, the first protecting pattern PT1 may be disposed adjacent to the first pixel area PX1, the second protecting pattern PT2 may be disposed adjacent to the second pixel area PX2, and the third protecting pattern PT3 may be disposed adjacent to the third pixel area PX3.

The first insulating pattern IP1, the second insulating pattern IP2, and the fourth insulating pattern IP4 may be disposed on the fourth insulating layer IL4. The first insulating pattern IP1 may be disposed in the first pixel area PX1. The first insulating pattern IP1 may cover (and contact) at least a portion of the first electrode PE1A. For example, the first insulating pattern IP1 may cover (and contact) a portion of the upper surface of the first electrode PE1A exposed through the first opening. For example, according to embodiments, the first insulating pattern IP1 may directly contact a portion of the upper surface of the first electrode PE1A exposed through the first opening. In addition, the first insulating pattern IP1 may cover (and contact) at least a portion of the first protecting pattern PT1. For example, according to embodiments, the first insulating pattern IP1 may directly contact at least a portion of the first protecting pattern PT1. For example, the first insulating pattern IP1 may entirely cover the first protecting pattern PT1. The second insulating pattern IP2 may be disposed in the second pixel area PX2. The second insulating pattern IP2 may cover (and contact, e.g., directly contact) at least a portion of the third electrode PE2A. For example, the second insulating pattern IP2 may cover (and contact, e.g., directly contact) a portion of the upper surface of the third electrode PE2A exposed through the second opening. In addition, the second insulating pattern IP2 may cover (and contact, e.g., directly contact) at least a portion of the second protecting pattern PT2. For example, the second insulating pattern IP2 may entirely cover the second protecting pattern PT2. The fourth insulating pattern IP4 may be disposed in the third pixel area PX3. The fourth insulating pattern IP4 may cover (and contact, e.g., directly contact) at least a portion of the fifth electrode PE3A. For example, the fourth insulating pattern IP4 may cover (and contact, e.g., directly contact) a portion of the upper surface of the fifth electrode PE3A exposed through the third opening. In addition, the fourth insulating pattern IP4 may cover (and contact, e.g., directly contact) at least a portion of the third protecting pattern PT3. For example, the fourth insulating pattern IP4 may entirely cover the third protecting pattern PT3. The first insulating pattern IP1, the second insulating pattern IP2, and the fourth insulating pattern IP4 may be spaced apart from each other in the plan view. Each of the first insulating pattern IP1, the second insulating pattern IP2, and the fourth insulating pattern IP4 may include inorganic materials such as, for example, silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other. In embodiments of the present disclosure, the first insulating pattern IP1, the second insulating pattern IP2, and the fourth insulating pattern IP4 may include substantially the same material and may be formed through substantially the same process.

The third insulating pattern IP3 may be disposed on the second insulating pattern IP2. The third insulating pattern IP3 may be disposed in the second pixel area PX2. The third insulating pattern IP3 may cover (and contact, e.g., directly contact) the second insulating pattern IP2. The fifth insulating pattern IP5 may be disposed on the fourth insulating pattern IP4. The fifth insulating pattern IP5 may be disposed in the third pixel area PX3. The fifth insulating pattern IP5 may cover (and contact, e.g., directly contact) the fourth insulating pattern IP4. Each of the third insulating pattern IP3 and the fifth insulating pattern IP5 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. In embodiments of the present disclosure, the third insulating pattern IP3 and the fifth insulating pattern IP5 may include substantially the same material and may be formed through substantially the same process.

The sixth insulating pattern IP6 may be disposed on the fifth insulating pattern IP5. The sixth insulating pattern IP6 may be disposed in the third pixel area PX3. The sixth insulating pattern IP6 may cover (and contact, e.g., directly contact) the fifth insulating pattern IP5. The sixth insulating pattern IP6 may include inorganic materials such as, for example, silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like.

According to embodiments of the present disclosure, the above-described configuration provides a protective multilayer structure that may enhances the environmental and chemical stability of the pixel electrodes. By covering side surfaces and upper surfaces of the electrodes PE1A, PE2A, and PE3A with protecting patterns PT1, PT2, and PT3, and subsequently covering those protecting patterns with insulating patterns IP1, IP2, and IP4, the electrode materials, such as metal layers susceptible to oxidation, are physically isolated from direct contact with potentially reactive dielectric layers. This structural separation may inhibit the diffusion of oxygen species from insulating materials like SiOx or SiOxNy into metal electrode layers, thereby preventing oxidation and preserving electrical performance. The use of amorphous carbon or similar oxidation-resistant materials for the protecting patterns may further improve the device’s resistance to environmental degradation. As a result, embodiments may maintain stable operation over time and exhibit improved luminance uniformity, reliability, and lifespan.

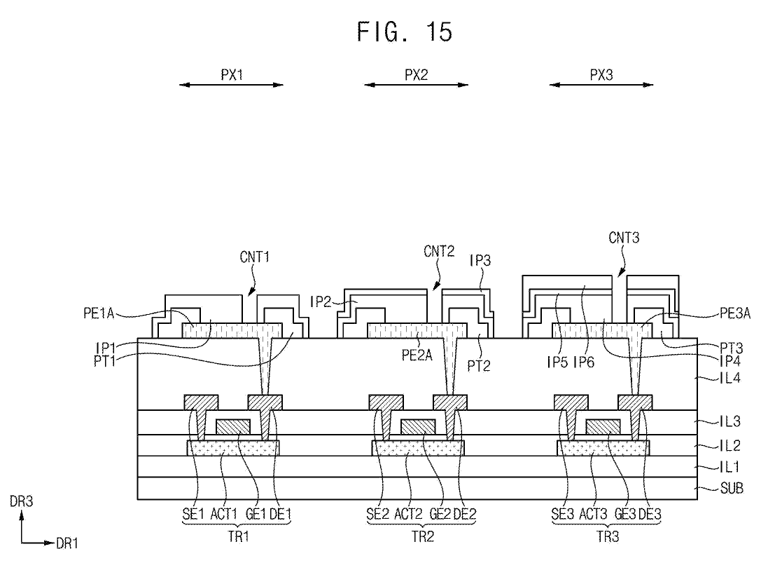

The second electrode PE1B may be disposed on (and in, e.g., penetrate through) the first insulating pattern IP1. The second electrode PE1B may be disposed in the first pixel area PX1. The second electrode PE1B may at least partially overlap the first electrode PE1A in the plan view. For example, the second electrode PE1B may entirely overlap the first electrode PE1A in the plan view. The second electrode PE1B may be connected to the first electrode PE1A. For example, the second electrode PE1B may be connected to the first electrode PE1A through a first contact hole penetrating (or, defining through) the first insulating pattern IP1 (e.g., a first contact hole CNT1 illustrated in FIG. 15). The first pixel electrode PE1 including the first electrode PE1A and the second electrode PE1B may be an anode electrode of the first light-emitting element LED1.

The fourth electrode PE2B may be disposed on the third insulating pattern IP3. The fourth electrode PE2B may be disposed in the second pixel area PX2. The fourth electrode PE2B may at least partially overlap the third electrode PE2A in the plan view. For example, the fourth electrode PE2B may entirely overlap the third electrode PE2A in the plan view. The fourth electrode PE2B may be connected to the third electrode PE2A. For example, the fourth electrode PE2B may be connected to the third electrode PE2A through a second contact hole penetrating (or, defining through) the second insulating pattern IP2 and the third insulating pattern IP3 (e.g., a second contact hole CNT2 illustrated in FIG. 15). The second pixel electrode PE2 including the third electrode PE2A and the fourth electrode PE2B may be an anode electrode of the second light-emitting element LED2.

The sixth electrode PE3B may be disposed on the sixth insulating pattern IP6. The sixth electrode PE3B may be disposed in the third pixel area PX3. The sixth electrode PE3B may at least partially overlap the fifth electrode PE3A in the plan view. For example, the sixth electrode PE3B may entirely overlap the fifth electrode PE3A in the plan view. The sixth electrode PE3B may be connected to the fifth electrode PE3A. For example, the sixth electrode PE3B may be connected to the fifth electrode PE3A through a third contact hole penetrating (or, defining through) the fourth insulating pattern IP4, the fifth insulating pattern IP5, and the sixth insulating pattern IP6 (e.g., a third contact hole CNT3 illustrated in FIG. 15). The third pixel electrode PE3 including the fifth electrode PE3A and the sixth electrode PE3B may be an anode electrode of the third light-emitting element LED3.

The pixel defining layer PDL may be disposed on the fourth insulating layer IL4. The pixel defining layer PDL may cover side surfaces of each of the second electrode PE1B, the fourth electrode PE2B, and the sixth electrode PE3B. For example, the pixel defining layer PDL may include a fourth opening exposing a portion of an upper surface of the second electrode PE1B, a fifth opening exposing a portion of an upper surface of the fourth electrode PE2B, and a sixth opening exposing a portion of an upper surface of the sixth electrode PE3B. In embodiments of the present disclosure, the pixel defining layer PDL may cover a portion of each of the first insulating pattern IP1, the second insulating pattern IP2, the third insulating pattern IP3, the fourth insulating pattern IP4, the fifth insulating pattern IP5, and the sixth insulating pattern IP6. The pixel defining layer PDL may be disposed between adjacent pixel areas of the plurality of pixel areas. For example, as illustrated in FIG. 2, the pixel defining layer PDL may be disposed between the first pixel area PX1 and the second pixel area PX2, and between the second pixel area PX2 and the third pixel area PX3. In embodiments of the present disclosure, the pixel defining layer PDL may include an inorganic material or an organic material. In embodiments of the present disclosure, the pixel defining layer PDL may include an organic material such as an epoxy resin or a siloxane resin. These materials may be used alone or in combination with each other. In embodiments of the present disclosure, the pixel defining layer PDL may further include a light-blocking material containing a black pigment, a black dye, and/or the like.

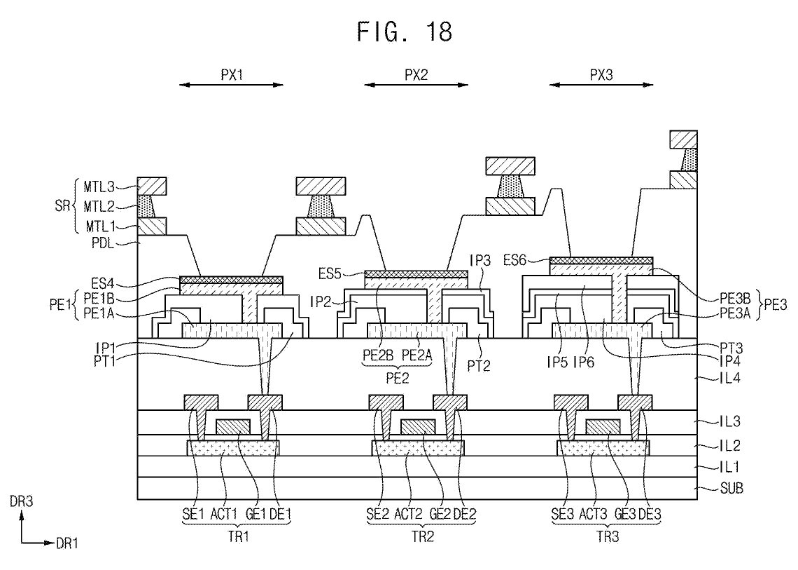

A first undercut area may be defined on the second electrode PE1B. The first undercut area may be an area where a portion of the upper surface of the second electrode PE1B and a portion of the pixel defining layer PDL are spaced apart from each other without contact. A first dummy pattern DP1 may be disposed in the first undercut area. The first dummy pattern DP1 may be a portion of a fourth etch stopper (e.g., a fourth etch stopper ES4 of FIG. 18) that remains without being removed. In embodiments of the present disclosure, the first dummy pattern DP1 may be omitted. A second undercut area may be defined on the fourth electrode PE2B. The second undercut area may be an area where a portion of the upper surface of the fourth electrode PE2B and a portion of the pixel defining layer PDL are spaced apart from each other without contact. A second dummy pattern DP2 may be disposed in the second undercut area. The second dummy pattern DP2 may be a portion of a fifth etch stopper (e.g., a fifth etch stopper ES5 of FIG. 18) that remains without being removed. In embodiments of the present disclosure, the second dummy pattern DP2 may be omitted. A third undercut area may be defined on the sixth electrode PE3B. The third undercut area may be an area where a portion of the upper surface of the sixth electrode PE3B and a portion of the pixel defining layer PDL are spaced apart from each other without contact. A third dummy pattern DP3 may be disposed in the third undercut area. The third dummy pattern DP3 may be a portion of a sixth etch stopper (e.g., a sixth etch stopper ES6 of FIG. 18) that remains without being removed. In embodiments of the present disclosure, the third dummy pattern DP3 may be omitted.

The separator SR may be disposed on the pixel defining layer PDL. The separator SR may at least partially overlap the pixel defining layer PDL in the plan view. The separator SR may be disposed between adjacent pixel areas of the plurality of pixel areas. For example, as illustrated in FIG. 2, the separator SR may be disposed between the first pixel area PX1 and the second pixel area PX2 and between the second pixel area PX2 and the third pixel area PX3.

In embodiments of the present disclosure, the separator SR may include a first metal pattern MTL1, a second metal pattern MTL2, and a third metal pattern MTL3. The first metal pattern MTL1 may be disposed on the pixel defining layer PDL, the second metal pattern MTL2 may be disposed on the first metal pattern MTL1, and the third metal pattern MTL3 may be disposed on the second metal pattern MTL2. Each of the first metal pattern MTL1 and the third metal pattern MTL3 may have a rectangular shape in a cross-sectional view, but this disclosure is not necessarily limited thereto. In embodiments of the present disclosure, a side surface of the second metal pattern MTL2 may have a tapered inclined surface. For example, the second metal pattern MTL2 may have a trapezoidal shape in a cross-sectional view. Each of the first metal pattern MTL1, the second metal pattern MTL2, and the third metal pattern MTL3 may include, for example, a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

The first intermediate layer EML1 may be disposed on the first pixel electrode PE1. For example, the first intermediate layer EML1 may be disposed on the second electrode PE1B. The first intermediate layer EML1 may be disposed in the first pixel area PX1. The first intermediate layer EML1 may cover a portion of the pixel defining layer PDL. The second intermediate layer EML2 may be disposed on the second pixel electrode PE2. For example, the second intermediate layer EML2 may be disposed on the fourth electrode PE2B. The second intermediate layer EML2 may be disposed in the second pixel area PX2. The second intermediate layer EML2 may cover a portion of the pixel defining layer PDL. The third intermediate layer EML3 may be disposed on the third pixel electrode PE3. For example, the third intermediate layer EML3 may be disposed on the sixth electrode PE3B. The third intermediate layer EML3 may be disposed in the third pixel area PX3. The third intermediate layer EML3 may cover a portion of the pixel defining layer PDL. In embodiments of the present disclosure, the first intermediate layer EML1, the second intermediate layer EML2, and the third intermediate layer EML3 may be disconnected (or, separated) from each other. For example, the first intermediate layer EML1 and the second intermediate layer EML2 may be disconnected (or, separated) from each other by the separator SR, and the second intermediate layer EML2 and the third intermediate layer EML3 may be disconnected (or, separated) from each other by the separator SR.

In embodiments of the present disclosure, each of the first intermediate layer EML1, the second intermediate layer EML2, and the third intermediate layer EML3 may have a tandem structure in which a first light-emitting unit, a second light-emitting unit, and a third light-emitting unit are stacked. The first light-emitting unit may include a first functional layer, a first light-emitting layer disposed on the first functional layer, and a second functional layer disposed on the first light-emitting layer. For example, the first functional layer may include a hole injection layer, a hole transport layer, and/or the like, and the second functional layer may include an electron transport layer, an electron injection layer, and/or the like. The first light-emitting layer may include a light-emitting material. The second light-emitting unit may include a third functional layer, a second light-emitting layer disposed on the third functional layer, and a fourth functional layer disposed on the second light-emitting layer. For example, the third functional layer may include a hole injection layer, a hole transport layer, and/or the like, and the fourth functional layer may include an electron transport layer, an electron injection layer, and/or the like. The second light-emitting layer may include a light-emitting material. The third light-emitting unit may include a fifth functional layer, a third light-emitting layer disposed on the fifth functional layer, and a sixth functional layer disposed on the third light-emitting layer. For example, the fifth functional layer may include a hole injection layer, a hole transport layer, and/or the like, and the sixth functional layer may include an electron transport layer, an electron injection layer, and/or the like. The third light-emitting layer may include a light-emitting material. In embodiments of the present disclosure, the first light-emitting layer, the second light-emitting layer, and the third light-emitting layer may emit light having different wavelengths from each other. For example, the first light-emitting layer may emit blue light, the second light-emitting layer may emit red light, and the third light-emitting layer may emit green light. However, this disclosure is not necessarily limited thereto.

This disclosure is not necessarily limited thereto, and in embodiments of the present disclosure, each of the first intermediate layer EML1, the second intermediate layer EML2, and the third intermediate layer EML3 may include a single light-emitting unit. For example, the first intermediate layer EML1 may include a light-emitting unit that emits red light, the second intermediate layer EML2 may include a light-emitting unit that emits green light, and the third intermediate layer EML3 may include a light-emitting unit that emits blue light. However, this disclosure is not necessarily limited thereto.

The first common electrode CE1 may be disposed on the first intermediate layer EML1. The first common electrode CE1 may be disposed in the first pixel area PX1. The first common electrode CE1 may be a cathode electrode of the first light-emitting element LED1. The second common electrode CE2 may be disposed on the second intermediate layer EML2. The second common electrode CE2 may be disposed in the second pixel area PX2. The second common electrode CE2 may be a cathode electrode of the second light-emitting element LED2. The third common electrode CE3 may be disposed on the third intermediate layer EML3. The third common electrode CE3 may be disposed in the third pixel area PX3. The third common electrode CE3 may be a cathode electrode of the third light-emitting element LED3. In embodiments of the present disclosure, the first common electrode CE1, the second common electrode CE2, and the third common electrode CE3 may be separated (or, disconnected) from each other. For example, the first common electrode CE1 and the second common electrode CE2 may be separated (or, disconnected) from each other by the separator SR, and the second common electrode CE2 and the third common electrode CE3 may be separated (or, disconnected) from each other by the separator SR. Each of the first common electrode CE1, the second common electrode CE2, and the third common electrode CE3 may include, for example, a metal, an alloy, a metal nitride, a conductive metal oxide, a transparent conductive material, and/or the like. These materials may be used alone or in combination with each other.

The encapsulation layer TFE may be disposed on the first common electrode CE1, the second common electrode CE2, the third common electrode CE3, and the separator SR. The encapsulation layer TFE may prevent impurities, moisture, and/or the like from penetrating into the first light-emitting element LED1, the second light-emitting element LED2, and the third light-emitting element LED3. The encapsulation layer TFE may include at least one inorganic encapsulation layer and at least one organic encapsulation layer. For example, the inorganic encapsulation layer and the organic encapsulation layer may be alternately stacked. For example, the inorganic encapsulation layer may include silicon oxide, silicon nitride, silicon oxynitride, and/or the like. These materials may be used alone or in combination with each other. The organic encapsulation layer may include a polymer cured material such as polyacrylate.

In embodiments of the present disclosure, a separation distance in a third direction DR3 between the first electrode PE1A and the second electrode PE1B, in an area not overlapping a first contact hole (e.g., a first contact hole CNT1 illustrated in FIG. 15) in the plan view, may be a first separation distance W1. For example, the first separation distance W1 may correspond to a height of the first contact hole in the third direction DR3. In embodiments of the present disclosure, a separation distance in the third direction DR3 between the third electrode PE2A and the fourth electrode PE2B, in an area not overlapping a second contact hole (e.g., a second contact hole CNT2 illustrated in FIG. 15) in the plan view, may be a second separation distance W2. For example, the second separation distance W2 may correspond to a height of the second contact hole in the third direction DR3. In embodiments of the present disclosure, a separation distance in the third direction DR3 between the fifth electrode PE3A and the sixth electrode PE3B, in an area not overlapping a third contact hole (e.g., a third contact hole CNT3 illustrated in FIG. 15) in the plan view, may be a third separation distance W3. For example, the third separation distance W3 may correspond to a height of the third contact hole in the third direction DR3.

As described above, the second electrode PE1B may be disposed on the first insulating pattern IP1. In addition, the third insulating pattern IP3 may be disposed on the second insulating pattern IP2, and the fourth electrode PE2B may be disposed on the third insulating pattern IP3. Accordingly, the second separation distance W2 may be different from the first separation distance W1. For example, the second separation distance W2 may be greater than the first separation distance W1. In addition, the fourth insulating pattern IP4 may be disposed on the third insulating pattern IP3, the fifth insulating pattern IP5 may be disposed on the fourth insulating pattern IP4, the sixth insulating pattern IP6 may be disposed on the fifth insulating pattern IP5, and the sixth electrode PE3B may be disposed on the sixth insulating pattern IP6. Accordingly, the third separation distance W3 may be different from each of the first separation distance W1 and the second separation distance W2. For example, the third separation distance W3 may be greater than each of the first separation distance W1 and the second separation distance W2.

In embodiments of the present disclosure, each of the second electrode PE1B, the fourth electrode PE2B, and the sixth electrode PE3B may function as a half mirror. For example, a portion of the light emitted from the first intermediate layer EML1 may be transmitted through the second electrode PE1B, and another portion of the light emitted from the first intermediate layer EML1 may be reflected by the second electrode PE1B. A portion of the light emitted from the second intermediate layer EML2 may be transmitted through the fourth electrode PE2B, and another portion of the light emitted from the second intermediate layer EML2 may be reflected by the fourth electrode PE2B. A portion of the light emitted from the third intermediate layer EML3 may be transmitted through the sixth electrode PE3B, and another portion of the light emitted from the third intermediate layer EML3 may be reflected by the sixth electrode PE3B.

In embodiments of the present disclosure, each of the first electrode PE1A, the third electrode PE2A, and the fifth electrode PE3A may function as a mirror. For example, light transmitted through the second electrode PE1B among the light emitted from the first intermediate layer EML1 may be reflected by the first electrode PE1A. Light transmitted through the fourth electrode PE2B among the light emitted from the second intermediate layer EML2 may be reflected by the third electrode PE2A. Light transmitted through the sixth electrode PE3B among the light emitted from the third intermediate layer EML3 may be reflected by the fifth electrode PE3A.

A portion of the light emitted from the first intermediate layer EML1 may be repeatedly reflected between the first electrode PE1A and the second electrode PE1B. The first separation distance W1 may be adjusted such that light of a specific wavelength resonates in the first pixel area PX1 through a microcavity effect and is emitted to an outside of the display device DD. For example, red light may resonate in the first pixel area PX1 through the microcavity effect and be emitted to the outside of the display device DD, however, this disclosure is not necessarily limited thereto. In addition, a portion of the light emitted from the second intermediate layer EML2 may be repeatedly reflected between the third electrode PE2A and the fourth electrode PE2B. The second separation distance W2 may be adjusted such that light of a specific wavelength resonates in the second pixel area PX2 through the microcavity effect and is emitted to the outside of the display device DD. For example, green light may resonate in the second pixel area PX2 through the microcavity effect and be emitted to the outside of the display device DD, however, this disclosure is not necessarily limited thereto. In addition, a portion of the light emitted from the third intermediate layer EML3 may be repeatedly reflected between the fifth electrode PE3A and the sixth electrode PE3B. The third separation distance W3 may be adjusted such that light of a specific wavelength resonates in the third pixel area PX3 through the microcavity effect and is emitted to the outside of the display device DD. For example, green light may resonate in the third pixel area PX3 through the microcavity effect and be emitted to the outside of the display device DD, however, this disclosure is not necessarily limited thereto. For example, as the number of stacked insulating patterns differs for each of the first pixel area PX1, the second pixel area PX2, and the third pixel area PX3, a resonance distance in each of the first pixel area PX1, the second pixel area PX2, and the third pixel area PX3 may be different from each other. For example, one insulating pattern (e.g., the first insulating pattern IP1) may be disposed in the first pixel area PX1, two insulating patterns (e.g., the second insulating pattern IP2 and the third insulating pattern IP3) may be disposed in the second pixel area PX2, and three insulating patterns (e.g., the fourth insulating pattern IP4, the fifth insulating pattern IP5, and the sixth insulating pattern IP6) may be disposed in the third pixel area PX3, such that wavelengths of lights resonated in each of the first pixel area PX1, the second pixel area PX2, and the third pixel area PX3 may be different from each other.

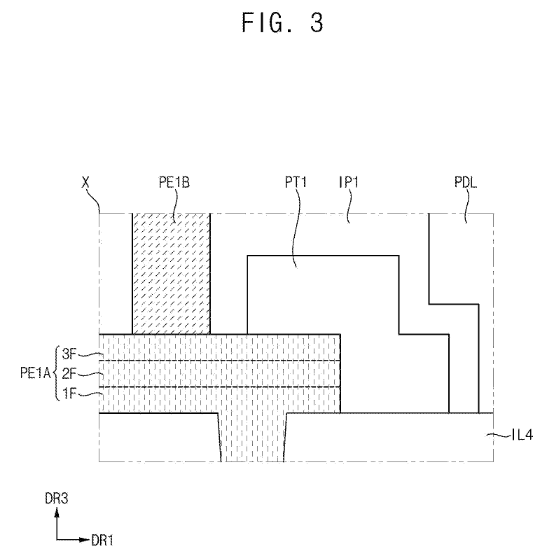

FIG. 3 is an enlarged cross-sectional view of an area X of FIG. 2.

Referring further to FIG. 3, in embodiments of the present disclosure, the first electrode PE1A may include a first layer 1F, a second layer 2F, and a third layer 3F. The second layer 2F may be disposed on the first layer 1F, and the third layer 3F may be disposed on the second layer 2F. In embodiments of the present disclosure, each of the first layer 1F and the third layer 3F may include indium gallium oxide (“IGO”), indium zinc oxide (“IZO”), indium tin oxide (“ITO”), indium zinc tin oxide (“IZTO”), indium gallium zinc oxide (“IGZO”), and/or the like. These materials may be used alone or in combination with each other. In embodiments of the present disclosure, the second layer 2F may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other.

In embodiments of the present disclosure, the first protecting pattern PT1 may cover an upper surface and a side surface of the third layer 3F. In embodiments of the present disclosure, the first protecting pattern PT1 may cover a side surface of the second layer 2F. In embodiments of the present disclosure, the first protecting pattern PT1 may cover a side surface of the first layer 1F.

The first protecting pattern PT1 may be an oxidation preventing film that prevents oxidation of a portion of the first electrode PE1A. For example, the first protecting pattern PT1 may prevent oxidation of the portion of the first electrode PE1A from the first insulating pattern IP1. For example, the first protecting pattern PT1 may prevent oxidation of a side surface of the first electrode PE1A from the first insulating pattern IP1. For example, the first protecting pattern PT1 may prevent oxidation of the second layer 2F from the first insulating pattern IP1. As described above, the first insulating pattern IP1 may include an inorganic material such as, for example, silicon oxide (“SiOₓ”), silicon oxynitride (“SiOₓN_{y}”), or silicon carbide (“SiOₓC_{y}”). Accordingly, when the first insulating pattern IP1 and the second layer 2F are in direct contact with each other, oxygen radicals and/or the like may move from the first insulating pattern IP1 to the second layer 2F. Therefore, a portion of the second layer 2F may be oxidized. For example, when the second layer 2F includes silver (“Ag”), oxygen radicals and/or the like may move from the first insulating pattern IP1 to the second layer 2F, and the silver (“Ag”) may be oxidized. According to embodiments of the present disclosure, the side surface of the first electrode PE1A and the first insulating pattern IP1 may be separated from each other by the first protecting pattern PT1. For example, a side surface of the second layer 2F and the first insulating pattern IP1 may be separated from each other by the first protecting pattern PT1. Therefore, oxidation of a portion of the second layer 2F may be prevented. According to embodiments, a side surface of the first electrode PE1A and the first insulating pattern IP1 may be discontinuous from each other, such that the two structures are physically separated by the first protecting pattern PT1. This discontinuity may prevent direct contact between the first insulating pattern IP1 and the reflective metal layer (e.g., the second layer 2F), thereby reducing the risk of oxidation.

In embodiments of the present disclosure, the first protecting pattern PT1 may serve as an oxidation preventing film that inhibits degradation of a portion of the first electrode PE1A. For example, the first protecting pattern PT1 may block oxidative interactions that would otherwise occur between the first electrode PE1A and the first insulating pattern IP1. For example, the first protecting pattern PT1 may prevent oxidation of a side surface of the first electrode PE1A – such as a side surface of a metal-containing second layer 2F – by providing a physical barrier between that layer and the adjacent dielectric. The first insulating pattern IP1 may include an inorganic oxide material such as, for example, silicon oxide (SiOx), silicon oxynitride (SiOxNy), or silicon oxycarbide (SiOxCy), which are known to release oxygen radicals during or after deposition. If such inorganic materials were to come into direct contact with the metal layer (e.g., silver) of the electrode, oxygen radicals could diffuse into the metal, leading to oxidation and a deterioration in electrical conductivity. In the configuration described herein, the first protecting pattern PT1 is interposed between the electrode and the insulating material, such that the side surface of the second layer 2F is not in direct contact with IP1. This spatial separation may prevent diffusion of oxygen-containing species into the metal layer, thereby suppressing oxidation and preserving the integrity of the electrode structure.

The protective architecture described above may be utilized in OLED display devices, where maintaining the conductivity and reflectivity of internal electrode layers has an effect on providing consistent luminance and color balance. Oxidation of reflective metal layers such as, for example, silver used for microcavity resonance, can impair the optical properties of the light-emitting structure, degrade device efficiency, and shorten operational lifespan. By preventing such oxidation through the use of the first protecting pattern PT1, embodiments of the present disclosure may provide high-fidelity light emission and improve long-term display stability.

In embodiments of the present disclosure, the first protecting pattern PT1 may include amorphous carbon. For example, the first protecting pattern PT1 may include carbon black, acetylene black, furnace black, and/or the like. These materials may be used alone or in combination with each other. However, this disclosure is not necessarily limited thereto, and any material classified as amorphous carbon may be usable as the first protecting pattern PT1. In addition, the first protecting pattern PT1 may include any material that can prevent oxidation of the second layer 2F.

Although the first electrode PE1A has been described with reference to FIG. 3, this disclosure is not necessarily limited thereto, and the third electrode PE2A and the fifth electrode PE3A may have substantially the same structure as the first electrode PE1A and may include substantially the same material as the first electrode PE1A. In addition, although the first protecting pattern PT1 has been described with reference to FIG. 3, this disclosure is not necessarily limited thereto, and the second protecting pattern PT2 and the third protecting pattern PT3 may have substantially the same structure as the first protecting pattern PT1 and may include substantially the same material as the first protecting pattern PT1.

FIG. 3 illustrates an enlarged cross-sectional view of a portion of the first pixel area PX1, showing the structural relationship between the first electrode PE1A, the first protecting pattern PT1, and the first insulating pattern IP1. As shown, the first electrode PE1A includes a multilayer structure comprising a first layer 1F, a second layer 2F, and a third layer 3F. According to embodiments, the first layer 1F and the third layer 3F may be formed of transparent conductive materials such as, e.g., indium gallium zinc oxide (IGZO), and the second layer 2F may be formed of, e.g., a reflective metal such as silver (Ag).

The first protecting pattern PT1 is disposed over the upper and side surfaces of the first electrode PE1A, and is formed of an oxidation-preventing material, such as, e.g., amorphous carbon. As illustrated in FIG. 3, the first protecting pattern PT1 covers the side surfaces of all three electrode layers (1F, 2F, and 3F), and may further extend over the top surface of the third layer 3F. Above the first protecting pattern PT1, the first insulating pattern IP1 is formed to cover the first protecting pattern PT1 and at least a portion of the exposed upper surface of the first electrode PE1A through an opening in the first protecting pattern PT1. In this manner, a step-like profile may be formed at the interface between the first protecting pattern PT1 and the insulating pattern IP1.

This step geometry may provide a distinct physical offset that separates the side surface of the reflective metal layer (e.g., the second layer 2F of the first electrode PE1A) from direct contact with the inorganic dielectric material of the first insulating pattern IP1, which may include, e.g., silicon oxide (SiOx), silicon oxynitride (SiOxNy), or similar compounds. By placing the first protecting pattern PT1 as a buffer between these materials, the structure in embodiments according to FIG. 3 may prevent diffusion of oxygen radicals from the dielectric into the metal electrode. Accordingly, embodiments of the present disclosure may allow for the use of a selectively patterned amorphous carbon layer to block oxidation and preserve the electrical and optical integrity of metal-based electrodes in a display device.

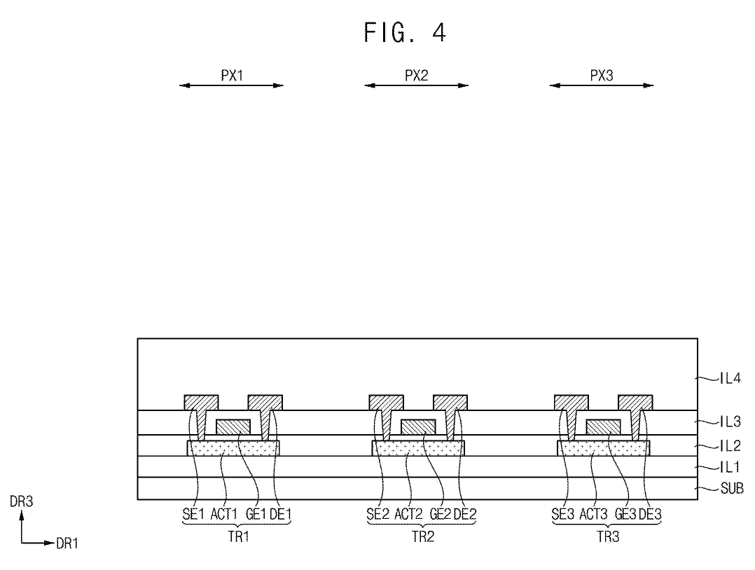

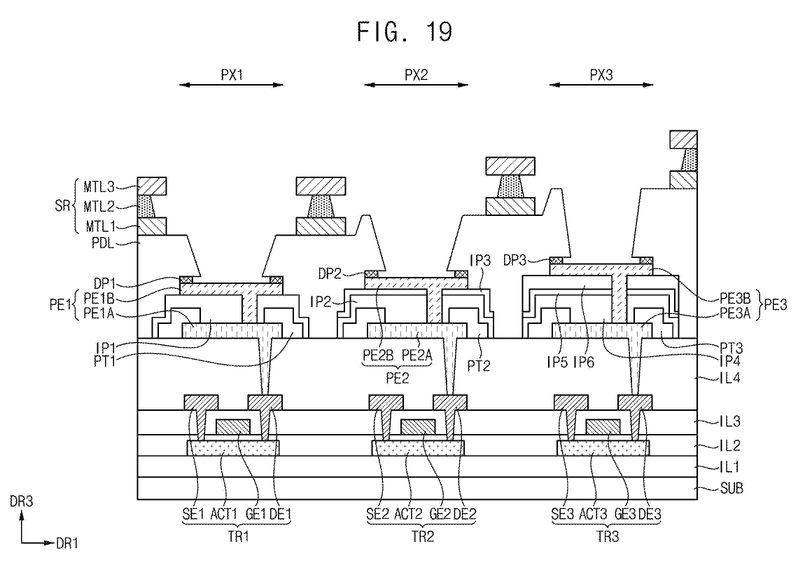

FIGS. 4 to 20 are cross-sectional views illustrating a method of manufacturing the display device of FIG. 2 according to embodiments of the present disclosure.

Referring to FIG. 4, the first insulating layer IL1 may be formed on the substrate SUB.

The substrate SUB may be formed of a transparent resin substrate. Example of the transparent resin substrate may include a polyimide substrate. In this case, the polyimide substrate may include a first organic layer, a first barrier layer, a second organic layer, and/or the like. In some embodiments, the substrate SUB may include a quartz substrate (e.g., a synthetic quartz substrate, a fluorine-doped quartz substrate), a calcium fluoride substrate, a sodalime glass substrate, a non-alkali glass substrate, and/or the like. These materials may be used alone or in combination with each other. The first insulating layer IL1 may include inorganic materials such as, for example, silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The first active pattern ACT1, the second active pattern ACT2, and the third active pattern ACT3 may be formed on the first insulating layer IL1. Each of the first active pattern ACT1, the second active pattern ACT2, and the third active pattern ACT3 may include a first contact area, a second contact area, and a channel area disposed between the first contact area and the second contact area. Each of the first active pattern ACT1, the second active pattern ACT2, and the third active pattern ACT3 may include an inorganic semiconductor (e.g., amorphous silicon, polysilicon, a metal oxide semiconductor,), an organic semiconductor, and/or the like. These materials may be used alone or in combination with each other. The metal oxide semiconductor may include, for example, a binary compound (“ABₓ”), a ternary compound (“ABₓC_{y}”), a quaternary compound (“ABₓC_{y}D_{z}”), and/or the like including indium (“In”), zinc (“Zn”), gallium (“Ga”), tin (“Sn”), titanium (“Ti”), aluminum (“Al”), hafnium (“Hf”), zirconium (“Zr”), magnesium (“Mg”), and/or the like. These materials may be used alone or in combination with each other. For example, the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), and indium gallium zinc oxide (“IGZO”). These materials may be used alone or in combination with each other.

The second insulating layer IL2 may be formed on the first insulating layer IL1. The second insulating layer IL2 may be formed to cover the first active pattern ACT1, the second active pattern ACT2, and the third active pattern ACT3. The second insulating layer IL2 may include inorganic materials such as, for example, silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The first gate electrode GE1, the second gate electrode GE2, and the third gate electrode GE3 may be formed on the second insulating layer IL2. The first gate electrode GE1 may be formed to overlap the channel area of the first active pattern ACT1 in the plan view. The second gate electrode GE2 may be formed to overlap the channel area of the second active pattern ACT2 in the plan view. The third gate electrode GE3 may be formed to overlap the channel area of the third active pattern ACT3 in the plan view. Each of the first gate electrode GE1, the second gate electrode GE2, and the third gate electrode GE3 may include, for example, a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

The third insulating layer IL3 may be formed on the second insulating layer IL2. The third insulating layer IL3 may be formed to cover the first gate electrode GE1, the second gate electrode GE2, and the third gate electrode GE3. The third insulating layer IL3 may include inorganic materials such as, for example, silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The first contact electrode SE1, the second contact electrode DE1, the third contact electrode SE2, the fourth contact electrode DE2, the fifth contact electrode SE3, and the sixth contact electrode DE3 may be formed on the third insulating layer IL3. The first hole may be formed in the second insulating layer IL2 and the third insulating layer IL3, and the first contact electrode SE1 may be formed to fill the first hole. The second hole may be formed in the second insulating layer IL2 and the third insulating layer IL3, and the second contact electrode DE1 may be formed to fill the second hole. The third hole may be formed in the second insulating layer IL2 and the third insulating layer IL3, and the third contact electrode SE2 may be formed to fill the third hole. The fourth hole may be formed in the second insulating layer IL2 and the third insulating layer IL3, and the fourth contact electrode DE2 may be formed to fill the fourth hole. The fifth hole may be formed in the second insulating layer IL2 and the third insulating layer IL3, and the fifth contact electrode SE3 may be formed to fill the fifth hole. The sixth hole may be formed in the second insulating layer IL2 and the third insulating layer IL3, and the sixth contact electrode DE3 may be formed to fill the sixth hole. Each of the first contact electrode SE1, the second contact electrode DE1, the third contact electrode SE2, the fourth contact electrode DE2, the fifth contact electrode SE3, and the sixth contact electrode DE3 may include, for example, a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

The fourth insulating layer IL4 may be formed on the third insulating layer IL3. The fourth insulating layer IL4 may be formed to cover the first contact electrode SE1, the second contact electrode DE1, the third contact electrode SE2, the fourth contact electrode DE2, the fifth contact electrode SE3 and the sixth contact electrode DE3. In embodiments of the present disclosure, the fourth insulating layer IL4 may include an organic material. For example, the fourth insulating layer IL4 may include phenolic resin, acrylic resin, polyimide resin, polyamide resin, siloxane resin, epoxy resin, and/or the like. These materials may be used alone or in combination with each other. This disclosure is not necessarily limited thereto, and in embodiments of the present disclosure, the fourth insulating layer IL4 may further include an inorganic material.

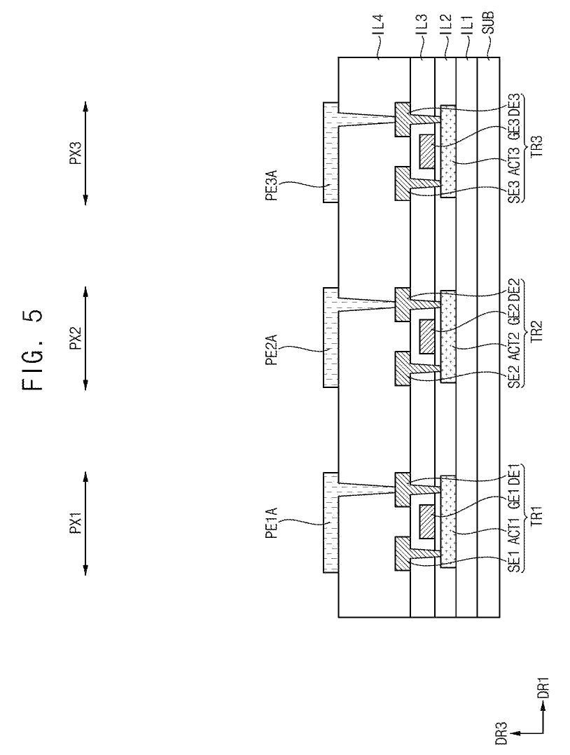

Referring to FIG. 5, the first electrode PE1A, the third electrode PE2A, and the fifth electrode PE3A may be formed on the fourth insulating layer IL4. The first electrode PE1A may be formed in the first pixel area PX1, the third electrode PE2A may be formed in the second pixel area PX2, and the fifth electrode PE3A may be formed in the third pixel area PX3. The seventh hole may be formed in the fourth insulating layer IL4, and the first electrode PE1A may be formed to fill the seventh hole. The eighth hole may be formed in the fourth insulating layer IL4, and the third electrode PE2A may be formed to fill the eighth hole. The ninth hole may be formed in the fourth insulating layer IL4, and the fifth electrode PE3A may be formed to fill the ninth hole.

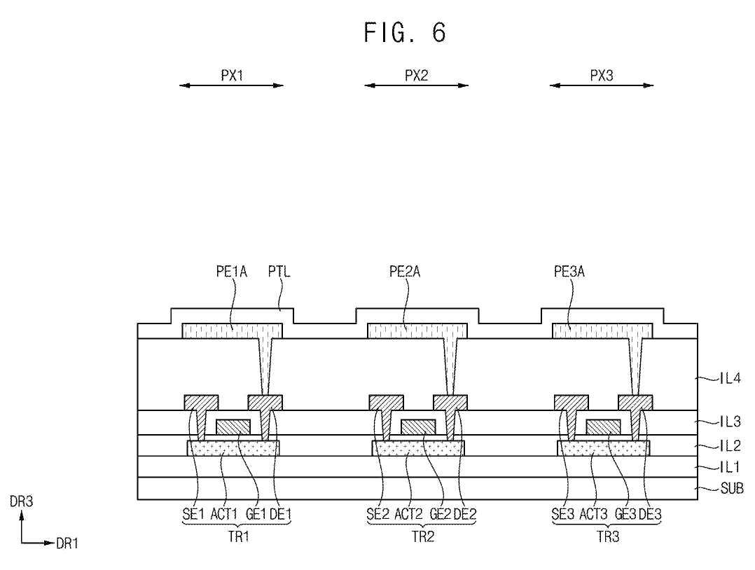

Referring to FIG. 6, a protecting layer PTL may be formed on the fourth insulating layer IL4. The protecting layer PTL may be formed to cover the first electrode PE1A, the third electrode PE2A, and the fifth electrode PE3A. In embodiments of the present disclosure, the protecting layer PTL may include amorphous carbon. For example, the protecting layer PTL may include carbon black, acetylene black, furnace black, and/or the like. These materials may be used alone or in combination with each other. However, this disclosure is not necessarily limited thereto, and any material classified as amorphous carbon may be usable as the protecting layer PTL.

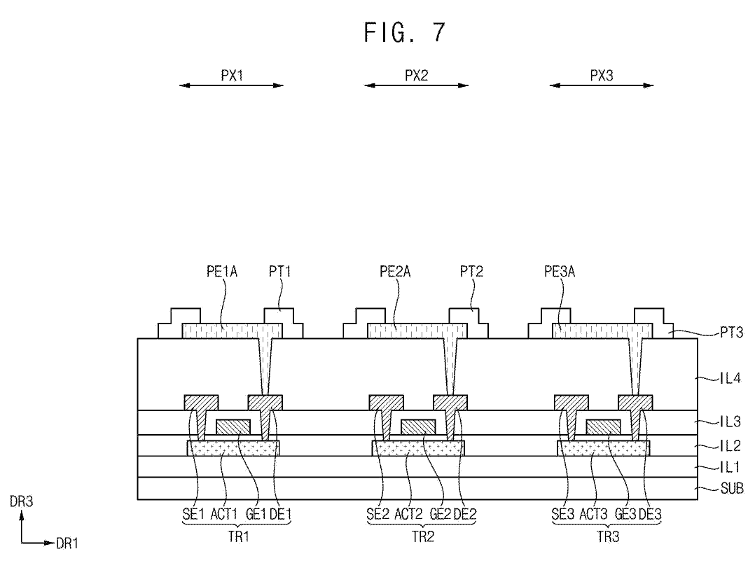

Referring to FIGS. 6 and 7, a portion of the protecting layer PTL may be removed. For example, portions of the protecting layer PTL disposed in the first pixel area PX1, the second pixel area PX2, and the third pixel area PX3 may be removed. In addition, a portion of the protecting layer PTL disposed in an area between adjacent pixel areas of the plurality of pixel areas may also be removed. For example, a portion of the protecting layer PTL disposed between the first pixel area PX1 and the second pixel area PX2 may be removed. In addition, a portion of the protecting layer PTL disposed between the second pixel area PX2 and the third pixel area PX3 may be removed. The portion of the protecting layer PTL may be removed through a dry etching process, however, this disclosure is not necessarily limited thereto. As the portion of the protecting layer PTL is removed, the first protecting pattern PT1, the second protecting pattern PT2, and the third protecting pattern PT3 may be formed.

According to embodiments of the present disclosure, the processes described above illustrate how the protecting patterns PT1, PT2, and PT3 – each serving as an oxidation-preventing structure – may be formed using a selectively etched amorphous carbon layer. By first forming a continuous protecting layer PTL over all relevant electrode regions and then removing only targeted portions of that layer, the resulting protecting patterns may precisely cover side and top surfaces of the electrodes that are most vulnerable to oxidation. This fabrication approach may enable the oxidation-preventing function of the protecting patterns to be realized in a manner compatible with standard thin-film processing techniques.

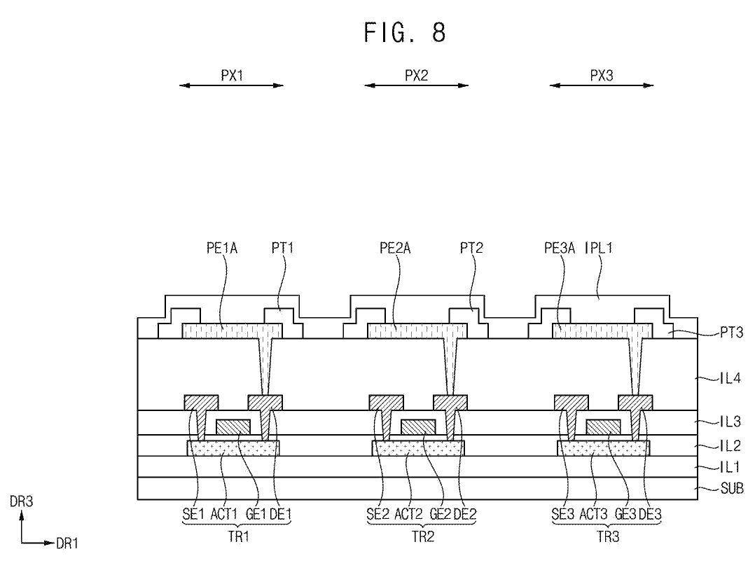

Referring to FIG. 8, a first preliminary insulating layer IPL1 may be formed on the fourth insulating layer IL4. The first preliminary insulating layer IPL1 may cover the first protecting pattern PT1, the second protecting pattern PT2, and the third protecting pattern PT3. In addition, the first preliminary insulating layer IPL1 may cover a portion of an upper surface of the first electrode PE1A, a portion of an upper surface of the third electrode PE2A, and a portion of an upper surface of the fifth electrode PE3A. The first preliminary insulating layer IPL1 may include inorganic materials such as, for example, silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

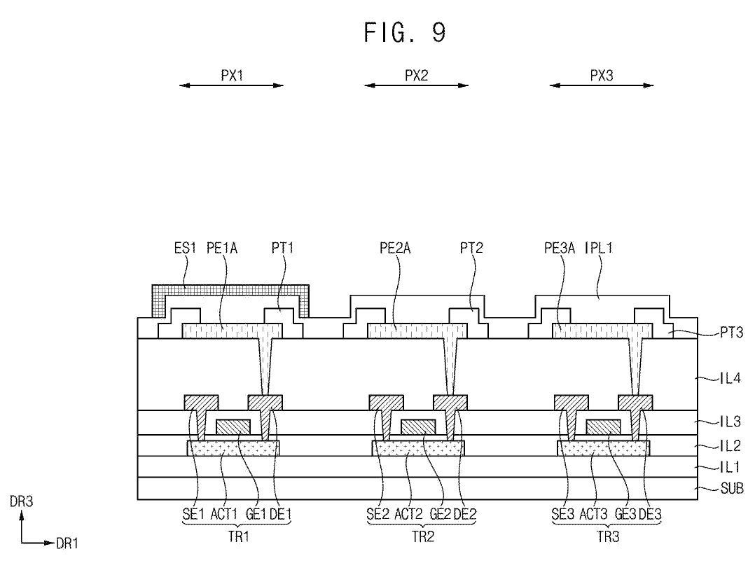

Referring to FIG. 9, a first etch stopper ES1 may be disposed on a first preliminary insulating layer IPL1. The first etch stopper ES1 may be formed in the first pixel area PX1. The first etch stopper ES1 may include, for example, gallium oxide, indium zinc oxide, indium tin oxide, hafnium oxide, titanium oxide, zirconium oxide, and/or the like. These materials may be used alone or in combination with each other. However, this disclosure is not necessarily limited thereto, and the first etch stopper ES1 may include other types of materials.

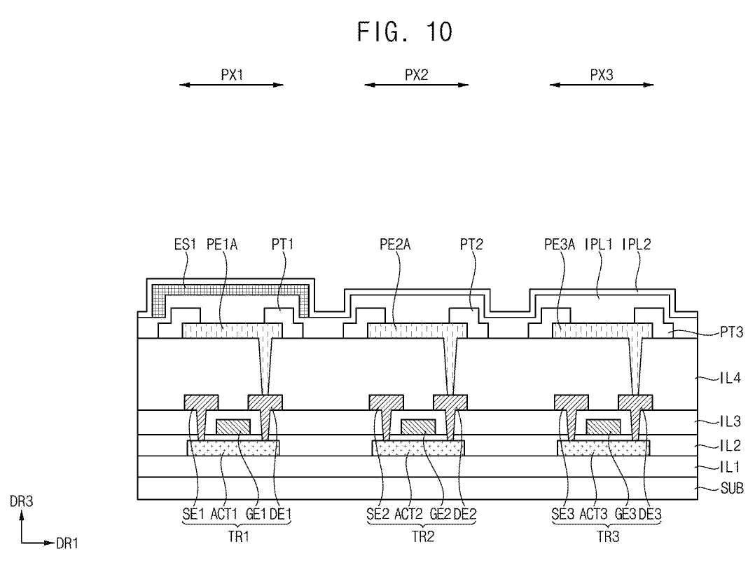

Referring to FIG. 10, a second preliminary insulating layer PIL2 may be formed on the first preliminary insulating layer PIL1. The second preliminary insulating layer PIL2 may be formed to cover the first etch stopper ES1. The second preliminary insulating layer PIL2 may include inorganic materials such as, for example, silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

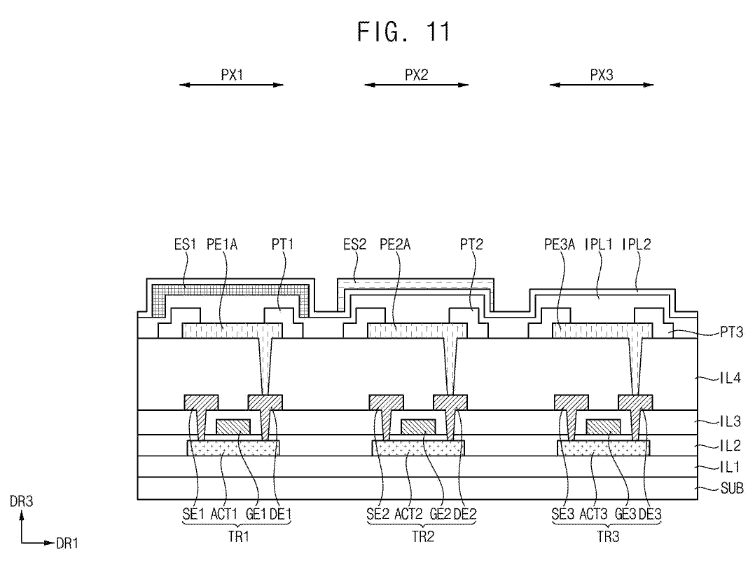

Referring to FIG. 11, a second etch stopper ES2 may be disposed on a second preliminary insulating layer PIL2. The second etch stopper ES2 may be formed in the second pixel area PX2. The second etch stopper ES2 may include, for example, gallium oxide, indium zinc oxide, indium tin oxide, hafnium oxide, titanium oxide, zirconium oxide, and/or the like. These materials may be used alone or in combination with each other. However, this disclosure is not necessarily limited thereto, and the second etch stopper ES2 may include other types of materials.

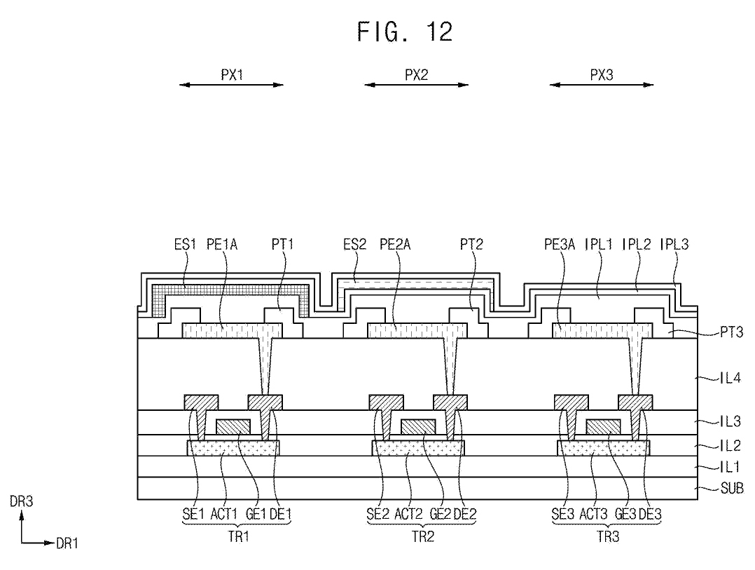

Referring to FIG. 12, a third preliminary insulating layer PIL3 may be formed on the second preliminary insulating layer PIL2. The third preliminary insulating layer PIL3 may be formed to cover the second etch stopper ES2. The third preliminary insulating layer PIL3 may include inorganic materials such as, for example, silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

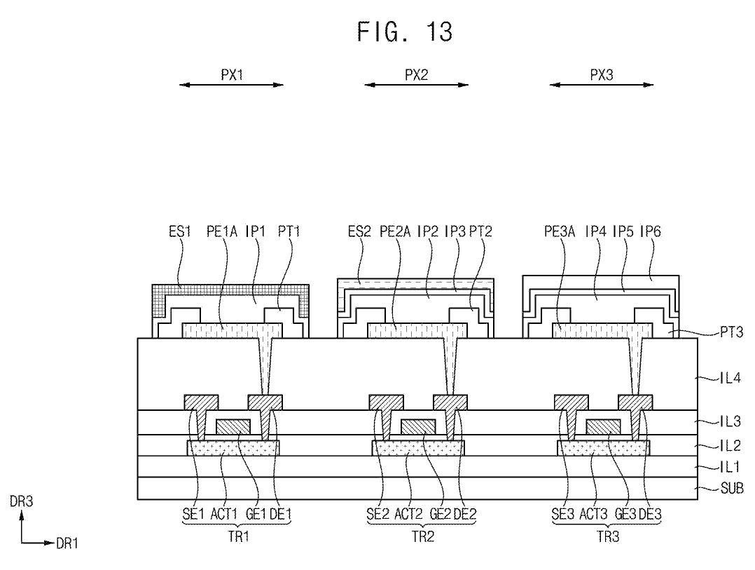

Referring to FIGS. 12 and 13, a portion of the first preliminary insulating layer PIL1 may be removed, and the first insulating pattern IP1, the second insulating pattern IP2, and the fourth insulating pattern IP4 may be formed. For example, portions of the first preliminary insulating layer PIL1 disposed in areas other than the first pixel area PX1, the second pixel area PX2, and the third pixel area PX3 may be removed through a dry etching process, and the first insulating pattern IP1, the second insulating pattern IP2, and the fourth insulating pattern IP4 may be formed. When the portion of the first preliminary insulating layer PIL1 is removed through the dry etching process, the first etch stopper ES1 may protect the first insulating pattern IP1 such that a portion of the first insulating pattern IP1 is not removed.

A portion of the second preliminary insulating layer PIL2 may be removed, and the third insulating pattern IP3 and the fifth insulating pattern IP5 may be formed. For example, portions of the second preliminary insulating layer PIL2 disposed in areas other than the second pixel area PX2 and the third pixel area PX3 may be removed through a dry etching process, and the third insulating pattern IP3 and the fifth insulating pattern IP5 may be formed. When the portion of the second preliminary insulating layer PIL2 is removed through the dry etching process, the second etch stopper ES2 may protect the third insulating pattern IP3 such that a portion of the third insulating pattern IP3 is not removed.

A portion of the third preliminary insulating layer PIL3 may be removed, and the sixth insulating pattern IP6 may be formed. For example, a portion of the third preliminary insulating layer PIL3 disposed in an area other than the third pixel area PX3 may be removed through a dry etching process, and the sixth insulating pattern IP6 may be formed.

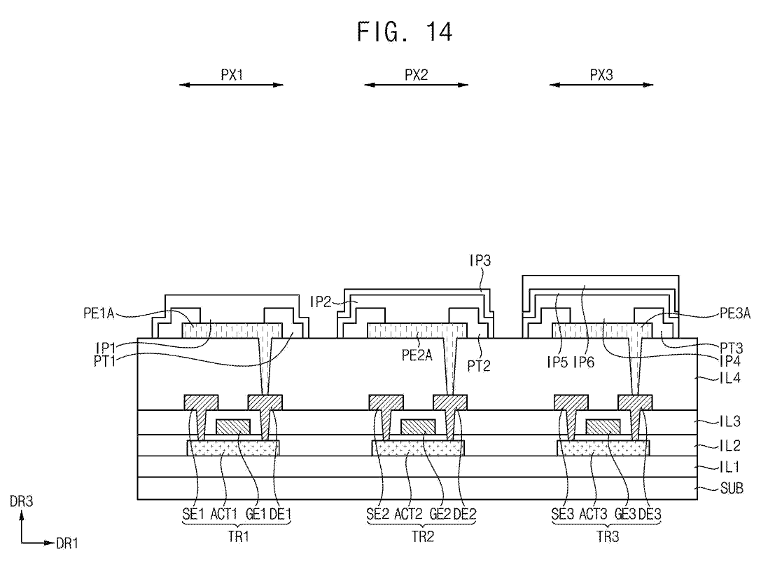

Referring to FIG. 14, each of the first etch stopper ES1 and the second etch stopper ES2 may be removed. For example, the first etch stopper ES1 and the second etch stopper ES2 may be removed by a wet etching process, but this disclosure is not necessarily limited thereto.

Referring to FIG. 15, a first contact hole CNT1 may be formed in the first protecting pattern PT1. For example, a portion of the first protecting pattern PT1 may be removed by a dry etching process to form the first contact hole CNT1. The first contact hole CNT1 may be formed in a portion of the first pixel area PX1. The first contact hole CNT1 may expose a portion of the upper surface of the first electrode PE1A.

A second contact hole CNT2 may be formed in the second protecting pattern PT2 and the third protecting pattern PT3. For example, portions of the second protecting pattern PT2 and the third protecting pattern PT3 may be removed by a dry etching process to form the second contact hole CNT2. The second contact hole CNT2 may be formed in a portion of the second pixel area PX2. The second contact hole CNT2 may expose a portion of the upper surface of the third electrode PE2A.

A third contact hole CNT3 may be formed in the fourth insulating pattern IP4, the fifth insulating pattern IP5, and the sixth insulating pattern IP6. For example, portions of the fourth insulating pattern IP4, the fifth insulating pattern IP5, and the sixth insulating pattern IP6 may be removed by a dry etching process to form the third contact hole CNT3. The third contact hole CNT3 may expose a portion of the upper surface of the fifth electrode PE3A.

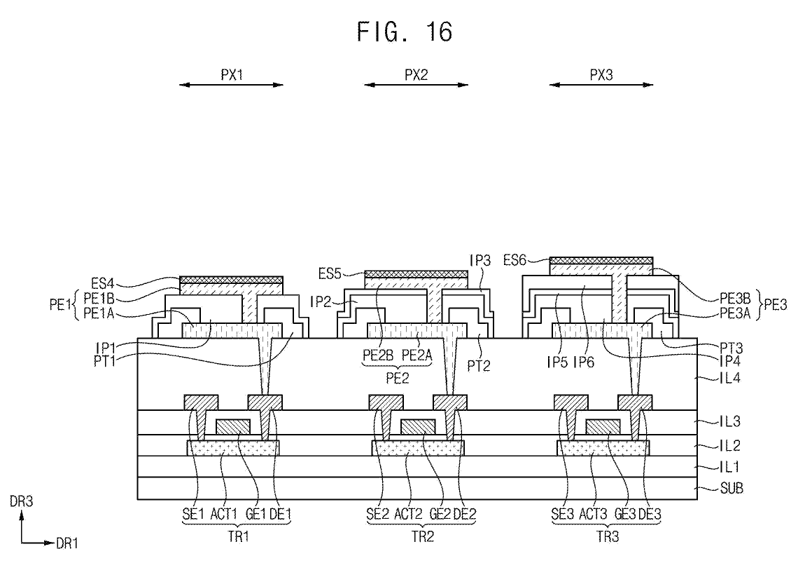

Referring to FIGS. 15 and 16, the second electrode PE1B may be formed on the first insulating pattern IP1. The second electrode PE1B may be formed to fill the first contact hole CNT1. Accordingly, the first pixel electrode PE1 including the first electrode PE1A and the second electrode PE1B may be formed. The fourth electrode PE2B may be formed on the third insulating pattern IP3. The fourth electrode PE2B may be formed to fill the second contact hole CNT2. Accordingly, the second pixel electrode PE2 including the third electrode PE2A and the fourth electrode PE2B may be formed. The sixth electrode PE3B may be formed on the sixth insulating pattern IP6. The sixth electrode PE3B may be formed to fill the third contact hole CNT3. Accordingly, the third pixel electrode PE3 including the fifth electrode PE3A and the sixth electrode PE3B may be formed.

A fourth etch stopper ES4 may be formed on the second electrode PE1B. The fourth etch stopper ES4 may be formed to overlap the second electrode PE1B in the plan view. A fifth etch stopper ES5 may be formed on the fourth electrode PE2B. The fifth etch stopper ES5 may be formed to overlap the fourth electrode PE2B in the plan view. A sixth etch stopper ES6 may be formed on the sixth electrode PE3B. The sixth etch stopper ES6 may be formed to overlap the sixth electrode PE3B in the plan view. Each of the fourth etch stopper ES4, the fifth etch stopper ES5, and the sixth etch stopper ES6 may include, for example, gallium oxide, indium zinc oxide, indium tin oxide, hafnium oxide, titanium oxide, zirconium oxide, and/or the like. These materials may be used alone or in combination with each other. However, this disclosure is not necessarily limited thereto, and each of the fourth etch stopper ES4, the fifth etch stopper ES5, and the sixth etch stopper ES6 may include other types of materials.

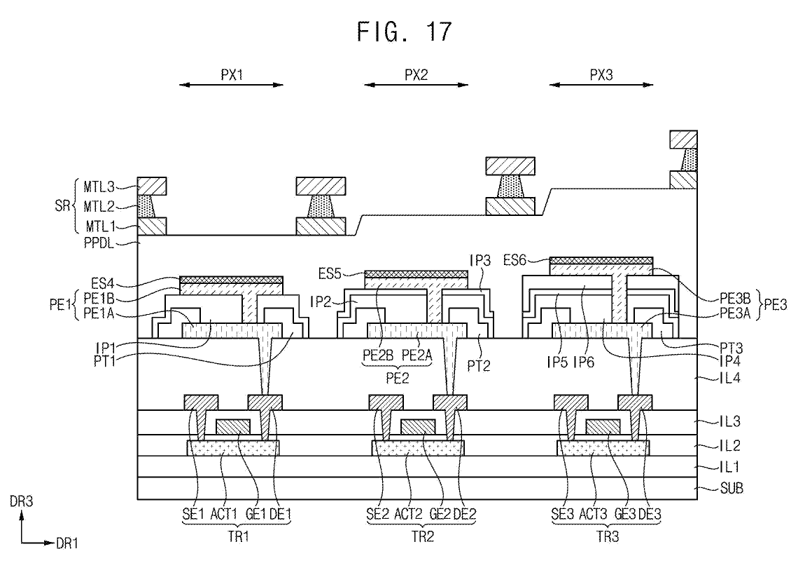

Referring to FIG. 17, a preliminary pixel defining layer PPDL may be formed on the fourth insulating layer IL4. The preliminary pixel defining layer PPDL may be formed to cover at least a portion of each of the first insulating pattern IP1, the second electrode PE1B, the fourth etch stopper ES4, the second insulating pattern IP2, the third insulating pattern IP3, the fourth electrode PE2B, the fifth etch stopper ES5, the fourth insulating pattern IP4, the fifth insulating pattern IP5, the sixth insulating pattern IP6, the sixth electrode PE3B, and the sixth etch stopper ES6.

The separator SR may be formed on the preliminary pixel defining layer PPDL. For example, a first preliminary metal layer may be formed on the preliminary pixel defining layer PPDL, a second preliminary metal layer may be formed on the first preliminary metal layer, and a third preliminary metal layer may be formed on the second preliminary metal layer. Portions of each of the first preliminary metal layer, the second preliminary metal layer, and the third preliminary metal layer disposed in the first pixel area PX1, the second pixel area PX2, and the third pixel area PX3 may be removed through a dry etching process. Accordingly, the first metal pattern MTL1, the second metal pattern MTL2, and the third metal pattern MTL3 may be formed.

Referring to FIGS. 17, 18, and 19, a portion of the preliminary pixel defining layer PPDL may be removed. For example, portions of the preliminary pixel defining layer PPDL disposed in the first pixel area PX1, the second pixel area PX2, and the third pixel area PX3 may be removed. Accordingly, the pixel defining layer PDL may be formed. When the portion of the preliminary pixel defining layer PPDL disposed in the first pixel area PX1 is removed, the fourth etch stopper ES4 may protect the second electrode PE1B such that a portion of the second electrode PE1B is not removed. When the portion of the preliminary pixel defining layer PPDL disposed in the first pixel area PX1 is removed, a portion of the fourth etch stopper ES4 may also be removed. Accordingly, the first dummy pattern DP1 may be formed. When the portion of the preliminary pixel defining layer PPDL disposed in the second pixel area PX2 is removed, the fifth etch stopper ES5 may protect the fourth electrode PE2B such that a portion of the fourth electrode PE2B is not removed. When the portion of the preliminary pixel defining layer PPDL disposed in the second pixel area PX2 is removed, a portion of the fifth etch stopper ES5 may also be removed. Accordingly, the second dummy pattern DP2 may be formed. When the portion of the preliminary pixel defining layer PPDL disposed in the third pixel area PX3 is removed, the sixth etch stopper ES6 may protect the sixth electrode PE3B such that a portion of the sixth electrode PE3B is not removed. When the portion of the preliminary pixel defining layer PPDL disposed in the third pixel area PX3 is removed, a portion of the sixth etch stopper ES6 may also be removed. Accordingly, the third dummy pattern DP3 may be formed.

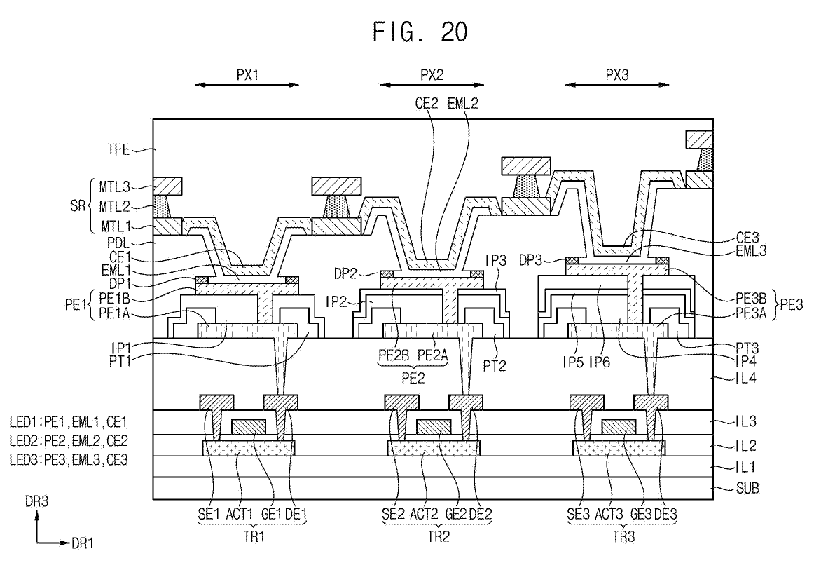

Referring to FIG. 20, the first intermediate layer EML1 may be formed on the second electrode PE1B. The first intermediate layer EML1 may be formed to cover a portion of the pixel defining layer PDL. The second intermediate layer EML2 may be formed on the fourth electrode PE2B. The second intermediate layer EML2 may be formed to cover a portion of the pixel defining layer PDL. The third intermediate layer EML3 may be formed on the sixth electrode PE3B. The third intermediate layer EML3 may be formed to cover a portion of the pixel defining layer PDL. In embodiments of the present disclosure, the first intermediate layer EML1, the second intermediate layer EML2, and the third intermediate layer EML3 may be separated (or, disconnected) from each other. For example, the first intermediate layer EML1 and the second intermediate layer EML2 may be separated (or, disconnected) from each other by the separator SR, and the second intermediate layer EML2 and the third intermediate layer EML3 may be separated (or, disconnected) from each other by the separator SR.

In embodiments of the present disclosure, each of the first intermediate layer EML1, the second intermediate layer EML2, and the third intermediate layer EML3 may have a tandem structure in which a first light-emitting unit, a second light-emitting unit, and a third light-emitting unit are stacked. The first light-emitting unit may include a first functional layer, a first light-emitting layer disposed on the first functional layer, and a second functional layer disposed on the first light-emitting layer. For example, the first functional layer may include a hole injection layer, a hole transport layer, and/or the like, and the second functional layer may include an electron transport layer, an electron injection layer, and/or the like. The first light-emitting layer may include a light-emitting material. The second light-emitting unit may include a third functional layer, a second light-emitting layer disposed on the third functional layer, and a fourth functional layer disposed on the second light-emitting layer. For example, the third functional layer may include a hole injection layer, a hole transport layer, and/or the like, and the fourth functional layer may include an electron transport layer, an electron injection layer, and/or the like. The second light-emitting layer may include a light-emitting material. The third light-emitting unit may include a fifth functional layer, a third light-emitting layer disposed on the fifth functional layer, and a sixth functional layer disposed on the third light-emitting layer. For example, the fifth functional layer may include a hole injection layer, a hole transport layer, and/or the like, and the sixth functional layer may include an electron transport layer, an electron injection layer, and/or the like. The third light-emitting layer may include a light-emitting material. In embodiments of the present disclosure, the first light-emitting layer, the second light-emitting layer, and the third light-emitting layer may emit light having different wavelengths from each other. For example, the first light-emitting layer may emit blue light, the second light-emitting layer may emit red light, and the third light-emitting layer may emit green light. However, this disclosure is not necessarily limited thereto.

In embodiments of the present disclosure, each of the first intermediate layer EML1, the second intermediate layer EML2, and the third intermediate layer EML3 may include a single light-emitting unit. For example, the first intermediate layer EML1 may include a light-emitting unit that emits red light, the second intermediate layer EML2 may include a light-emitting unit that emits green light, and the third intermediate layer EML3 may include a light-emitting unit that emits blue light. However, this disclosure is not necessarily limited thereto.

The first common electrode CE1 may be formed on the first intermediate layer EML1. The first common electrode CE1 may be formed in the first pixel area PX1. The second common electrode CE2 may be formed on the second intermediate layer EML2. The second common electrode CE2 may be formed in the second pixel area PX2. The third common electrode CE3 may be formed on the third intermediate layer EML3. The third common electrode CE3 may be formed in the third pixel area PX3.

The first common electrode CE1 may be formed on the first intermediate layer EML1. The first common electrode CE1 may be formed in the first pixel area PX1. The second common electrode CE2 may be formed on the second intermediate layer EML2. The second common electrode CE2 may be formed in the second pixel area PX2. The third common electrode CE3 may be formed on the third intermediate layer EML3. The third common electrode CE3 may be formed in the third pixel area PX3. In embodiments of the present disclosure, the first common electrode CE1, the second common electrode CE2, and the third common electrode CE3 may be separated (or, disconnected) from each other. For example, the first common electrode CE1 and the second common electrode CE2 may be separated (or, disconnected) from each other by the separator SR, and the second common electrode CE2 and the third common electrode CE3 may be separated (or, disconnected) from each other by the separator SR. Each of the first common electrode CE1, the second common electrode CE2, and the third common electrode CE3 may include, for example, a metal, an alloy, a metal nitride, a conductive metal oxide, a transparent conductive material, and/or the like. These materials may be used alone or in combination with each other.

The encapsulation layer TFE may be formed on the first common electrode CE1, the second common electrode CE2, the third common electrode CE3, and the separator SR. The encapsulation layer TFE may include at least one inorganic encapsulation layer and at least one organic encapsulation layer. For example, the inorganic encapsulation layer and the organic encapsulation layer may be alternately stacked. For example, the inorganic encapsulation layer may include silicon oxide, silicon nitride, silicon oxynitride, and/or the like. These materials may be used alone or in combination with each other. The organic encapsulation layer may include a polymer cured material such as polyacrylate.

The display device (e.g., the display device DD of FIG. 1) according to embodiments may be applied to various electronic devices. An electronic device according to embodiments may include the above-described display device, and may further include a module or device having other additional functions in addition to the display device.

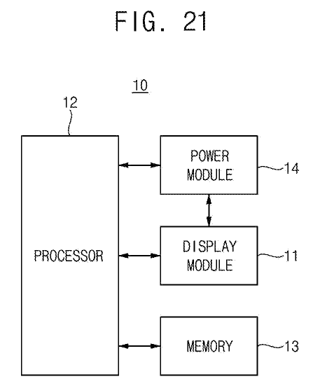

FIG. 21 is a block diagram illustrating an electronic device according to embodiments of the present disclosure.

Referring to FIG. 21, an electronic device 10 according to embodiments may include a display module 11, a processor 12, a memory 13, and a power module 14.

The processor 12 may include at least one of, for example, a central processing unit (“CPU”), an application processor (“AP”), a graphic processing unit (“GPU”), a communication processor (“CP”), an image signal processor (“ISP”), and a controller.

Data information utilized for operation of the processor 12 or the display module 11 may be stored in the memory 15. When the processor 12 executes an application stored in the memory 15, an image data signal and/or an input control signal is transmitted to the display module 11, and the display module 11 may process received signal and output image information through a display screen.

The power module 14 may include a power supply module such as a power adapter or a battery device, and a power conversion module that converts power supplied by the power supply module to generate power required for operation of the electronic device 10.

At least one of components of the electronic device 10 described above may be included in the display device according to the above-described embodiments. In addition, some of individual modules functionally included in one module may be included in the display device, and others may be provided separately from the display device. For example, the display device may include the display module 11, and the processor 12, the memory 13, and the power module 14 may be provided in form of another device in the electronic device 10 other than the display device.

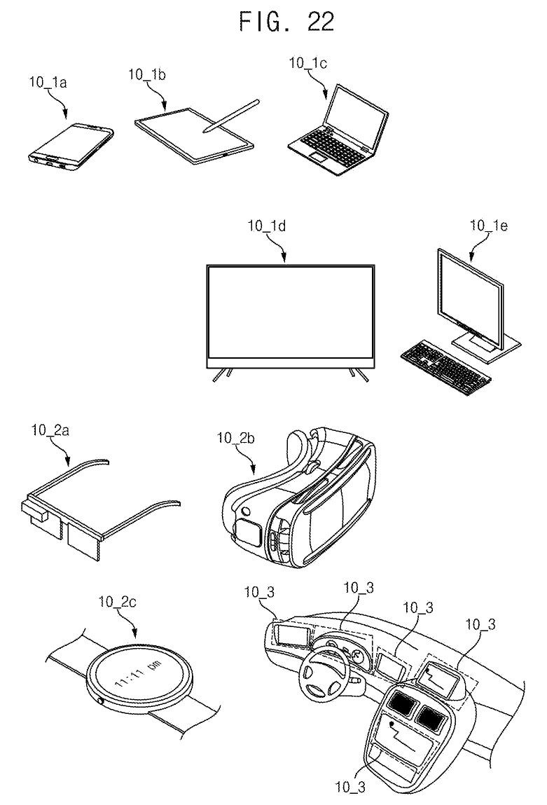

FIG. 22 is a schematic diagram of an electronic device according to various embodiments of the present disclosure.

Referring to FIG. 22, various electronic devices to which display devices according to embodiments are applied may include not only electronic devices for image display such as, for example, a smartphone 10_1a, a tablet PC 10_1b, a laptop 10_1c, a TV 10_1d, a desk monitor 10_1e, and/or the like, but also wearable electronic devices including display modules such as, for example, smart glasses 10_2a, a head mounted display 10_2b, a smart watch 10_2c, and/or the like, a vehicle electronic device 10_3 including display modules such as, for example, a vehicle's instrument panel, a center fascia, a center information display (“CID”) disposed on a dashboard, a room mirror display, and/or the like.

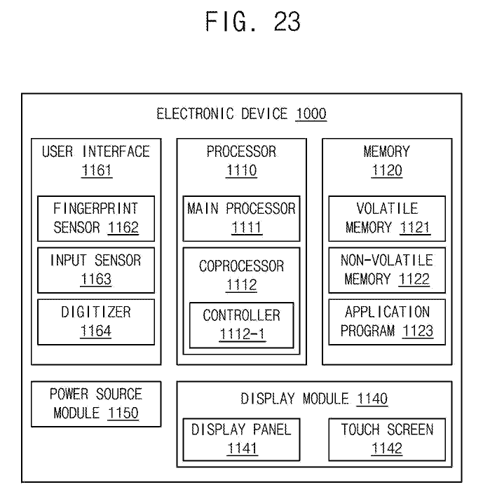

FIG. 23 is a diagram illustrating an electronic device according to an embodiment of the present invention.

Referring to FIG. 23, the electronic device 1000 according to an embodiment of the present disclosure may output various information (e.g., images, text, music, etc.) through a display module 1140, which, for example, may correspond to the display device DD described above. When a processor 1110 executes an application stored in a memory 1120, the display module 1140 may provide application information to a user through a display panel 1141.

In some embodiments, the electronic device 1000 may be configured as a smartphone, camera, smart TV, monitor, smartwatch, tablet, automotive display, or AR/VR headset. For example, the electronic device 1000 may be a smartphone including a touch-sensitive display area DA for interaction and a non-display area NDA including sensors and circuits for enhanced functionality. For example, the electronic device 1000 may be a television or monitor including a large display area DA for high-resolution video playback and a non-display area NDA incorporating driving circuits or connectivity modules for external inputs. For example, the electronic device 1000 may be a smartwatch including a display area DA optimized for compact and high-clarity visuals and a non-display area NDA integrating biometric sensors for health monitoring. In some cases, the electronic device 1000 be an AR/VR headset.

In some embodiments, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device DD described above.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may be included in the display device DD described above. For example, the components described above and illustrated in the figures may be included in the display panel 1141.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

The present disclosure can be applied to various display devices. For example, the present disclosure is applicable to various display devices such as display devices for vehicles, ships and aircraft, portable communication devices, display devices for exhibition or information transmission, medical display devices, and the like.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A display device, comprising:
a first electrode disposed in a first pixel area on a substrate;
a first protecting pattern covering at least a portion of the first electrode;
a first insulating pattern covering at least a portion of each of the first electrode and the first protecting pattern;
a second electrode disposed on the first insulating pattern and at least partially overlapping the first electrode in a plan view,
wherein the second electrode is connected to the first electrode;
a third electrode disposed in a second pixel area spaced apart from the first pixel area in the plan view on the substrate;
a second protecting pattern covering at least a portion of the third electrode;
a second insulating pattern covering at least a portion of each of the third electrode and the second protecting pattern; and
a fourth electrode disposed on the second insulating pattern and at least partially overlapping the third electrode in the plan view,
wherein the fourth electrode is connected to the third electrode.

2. The display device of claim 1, wherein the first protecting pattern covers a side surface of the first electrode, and the second protecting pattern covers a side surface of the third electrode.

3. The display device of claim 2, wherein the first protecting pattern further covers an upper surface of the first electrode, and the second protecting pattern further covers an upper surface of the third electrode.

4. The display device of claim 1, further comprising:
a third insulating pattern covering the second insulating pattern,
wherein the fourth electrode is disposed on the third insulating pattern.

5. The display device of claim 4, wherein the first electrode and the second electrode are connected to each other through a first contact hole formed in the first insulating pattern.

6. The display device of claim 5, wherein the third electrode and the fourth electrode are connected to each other through a second contact hole formed in the second insulating pattern and the third insulating pattern.

7. The display device of claim 6, wherein a distance between the third electrode and the fourth electrode in an area not overlapping the second contact hole in the plan view is greater than a distance between the first electrode and the second electrode in an area not overlapping the first contact hole in the plan view.

8. The display device of claim 1, wherein each of the first protecting pattern and the second protecting pattern includes amorphous carbon.

9. The display device of claim 1, wherein the first protecting pattern is an oxidation preventing film that prevents oxidation of at least a portion of the first electrode, and the second protecting pattern is an oxidation preventing film that prevents oxidation of at least a portion of the third electrode.

10. The display device of claim 1, wherein a side surface of the first electrode and the first insulating pattern are discontinuous from each other.

11. A method of manufacturing a display device, the method comprising:
forming a first electrode in a first pixel area on a substrate;
forming a first protecting pattern covering at least a portion of the first electrode;
forming a first insulating pattern covering at least a portion of the first protecting pattern;
forming a first contact hole in the first insulating pattern;
forming a second electrode on the first insulating pattern, wherein the second electrode fills the first contact hole;
forming a third electrode in a second pixel area spaced apart from the first pixel area in a plan view on the substrate;
forming a second protecting pattern covering at least a portion of the third electrode;
forming a second insulating pattern covering at least a portion of the second protecting pattern;
forming a third insulating pattern covering the second insulating pattern;
forming a second contact hole in the second insulating pattern and the third insulating pattern; and
forming a fourth electrode on the second insulating pattern, wherein the fourth electrode fills the second contact hole.

12. The method of claim 11, wherein forming the first protecting pattern and the second protecting pattern comprises:
forming a protecting layer covering the first electrode and the third electrode; and
removing portions of the protecting layer in the first pixel area and the second pixel area.

13. The method of claim 11, wherein forming the first insulating pattern comprises:
forming a preliminary insulating layer covering the first protecting pattern and the second protecting pattern;
forming an etch stopper in the first pixel area on the preliminary insulating layer; and
removing at least a portion of the preliminary insulating layer.

14. An electronic device, comprising:
a display device, comprising:
a power source configured to supply power to a display panel, wherein the display panel comprises:
a first electrode disposed in a first pixel area on a substrate;
a first protecting pattern covering at least a portion of the first electrode;
a first insulating pattern covering at least a portion of each of the first electrode and the first protecting pattern;
a second electrode disposed on the first insulating pattern and at least partially overlapping the first electrode in a plan view,
wherein the second electrode is connected to the first electrode;
a third electrode disposed in a second pixel area spaced apart from the first pixel area on the substrate;
a second protecting pattern covering at least a portion of the third electrode;
a second insulating pattern covering at least a portion of each of the third electrode and the second protecting pattern; and
a fourth electrode disposed on the second insulating pattern and at least partially overlapping the third electrode in the plan view,
wherein the fourth electrode is connected to the third electrode.

15. The electronic device of claim 14, wherein the first protecting pattern covers a side surface of the first electrode, and the second protecting pattern covers a side surface of the third electrode.

16. The electronic device of claim 15, wherein the first protecting pattern further covers an upper surface of the first electrode, and the second protecting pattern further covers an upper surface of the third electrode.

17. The electronic device of claim 14, further comprising:
a third insulating pattern covering the second insulating pattern,
wherein the fourth electrode is disposed on the third insulating pattern.

18. The electronic device of claim 14, wherein each of the first protecting pattern and the second protecting pattern includes amorphous carbon.

19. The electronic device of claim 14, wherein the first protecting pattern is an oxidation preventing film that prevents oxidation of at least a portion of the first electrode, and the second protecting pattern is an oxidation preventing film that prevents oxidation of at least a portion of the third electrode.

20. The electronic device of claim 14, further comprising:
a processor;
a memory having stored application programs for execution by the processor; and
a user interface configured to sense user input via touch or cursor select of an icon presented on the display panel,
wherein upon receipt of the user input, the processor is caused to execute one or more of the stored application programs to perform functions of one or more of a smartphone, camera, smart TV, monitor, smartwatch, tablet, automotive display, or AR/VR headset.
